(19) United States
(12) Patent Application Publication
(10) Pub. No.: US 2024/0200183 A1
(43) Pub. Date: Jun. 20, 2024

(54) DEVICES AND METHODS FOR SPUTTERING AT LEAST TWO ELEMENTS

(71) Applicant: TechIFab GmbH, Radeberg (DE)

(72) Inventors: Heidemarie SCHMIDT, Dresden (DE); Danilo BUERGER, Dresden (DE)

(21) Appl. No.: 18/541,027

(22) Filed: Dec. 15, 2023

(30) Foreign Application Priority Data
Dec. 16, 2022 (DE) 10 2022 133 601.8

(51) Int. Cl. C23C 14/14; C23C 14/34; C23C 14/54

(52) U.S. Cl. CPC C23C 14/14; C23C 14/34; C23C 14/541; C23C 14/548

(57) ABSTRACT

According to various aspects, a method is provided including: depositing a material layer on a substrate, wherein the material layer includes at least a first element and a second element in a predefined atomic ratio, wherein the first element has a higher temperature-dependent re-evaporation rate from the substrate and/or the material layer than the second element; wherein depositing the material layer includes: generating a deposition material stream for deposition on the substrate, wherein the deposition material stream includes an atomic ratio of the first element to the second element higher than the predefined atomic ratio, and setting a temperature of the substrate to evaporate atoms of the first element from the substrate and/or the material layer such that the material layer has the predefined atomic ratio of the first element and the second element.

### CROSS-REFERENCE TO RELATED APPLICATIONS

This non-provisional application claims priority to German Application DE 10 2022 133 601.8, which was filed on Dec. 16, 2022, the entire contents of which are incorporated herein by reference.

### TECHNICAL FIELD

Various aspects relate to devices and methods for sputtering at least a first element and a second element. According to various aspects, the devices and methods allow to generate a material layer which includes the first element and the second element in a predefined atomic ratio.

### BACKGROUND

In general, material layers (e.g., thin films) may be generated using a variety of physical vapor deposition or chemical vapor deposition processes. As an example, a material layer including two or more elements may be deposited on a substrate using (e.g., magnetron) sputtering. For various applications, such as memristive devices or memristors, properties (e.g., memristive switching properties) may strongly depend a stoichiometry of the material, such as an atomic ratio between at least two elements of the two or more elements. Therefore, in order to achieve desired properties, it may be required that the deposited material layer has a predefined stoichiometry (e.g., a predefined atomic ratio between at least two elements). However, when sputtering the two or more elements, several factors may impact the sputtering process and, hence, the stoichiometry of the finally deposited material layer.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIGS. 1A to 1C each show at least part of a system according to various aspects;

FIGS. 2A to 2H each shows aspects of a respective configuration of a sputter source capable to sputter from at least two sputter targets according to various aspects;

FIG. 3 exemplarily shows a respective evaporation pressure curve of bismuth and iron as a function of pressure and temperature;

FIG. 4 exemplarily shows a functional correlation between a first power applied to sputter bismuth and a second power applied to sputter iron in order to generate, when reactively sputtering in an oxidic atmosphere, a material layer which substantially consists of bismuth ferrite having a predefined ratio between bismuth and iron of 1:1;

FIG. 5 exemplarily shows respective current-voltage characteristics of memristive devices, which include a sputtered bismuth ferrite material layer, depending on their location on a wafer;

FIG. 6 shows an elemental distribution of a bismuth ferrite material layer which has been sputtered on a platinum, titanium, silicon oxide substrate at 700° C. and an elemental distribution of a bismuth ferrite material layer which has been sputtered on a platinum, titanium, silicon oxide substrate at 600° C.;

FIG. 7 to FIG. 18 each shows a flow diagram of a respective method for sputtering at least a first element and a second element according to various aspects.

### DESCRIPTION

The following detailed description refers to the accompanying drawings that show, by way of illustration, specific details, and aspects in which the invention may be practiced. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects can be combined with one or more other aspects to form new aspects. Various aspects are described in connection with methods and various aspects are described in connection with devices (e.g., arrangements). However, it may be understood that aspects described in connection with methods may similarly apply to the devices, and vice versa.

The term “element”, as used herein, may refer to a chemical element (e.g., a chemical element of the periodic table).

In some aspects, two physical and/or chemical properties (e.g., an electrical voltage, an electrical current, an electrical conductance, a thickness, an electrical conductivity, a doping concentration, as examples) may be compared with one another by relative terms such as “greater”, “higher”, “lower”, “less”, or “equal”, for example. It is understood that, in some aspects, a comparison may include a sign (positive or negative) of a value representing the physical and/or chemical properties or, in other aspects, the absolute values are considered for the comparison. However, a comparison of measurement values representing a physical and/or chemical property may usually include a measurement of such measurement values by the same measurement principle or at least by comparable measurement principles.

The term “processor” as used herein may be understood as any kind of technological entity that allows handling of data. The data may be handled according to one or more specific functions that the processor may execute. Further, a processor as used herein may be understood as any kind of circuit, e.g., any kind of analog or digital circuit. A processor may thus be or include an analog circuit, digital circuit, mixed-signal circuit, logic circuit (e.g., a hard-wired logic circuit or a programmable logic circuit), microprocessor (for example a Complex Instruction Set Computer (CISC) processor or a Reduced Instruction Set Computer (RISC) processor), Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. A “processor” may also be a logic-implementing entity executing software, for example any kind of computer program, for example a computer program using a virtual machine code such as for example Java. A “processor” as used herein may also include any kind of cloud-based processing system that allows handling of data in a distributed manner, e.g. with a plurality of logic-implementing entities communicatively coupled with one another (e.g. over the internet) and each assigned to handling the data or part of the data. By way of illustration, an application running on a server and the server can also be a “processor”. Any other kind of implementation of the respective functions, which will be described below in further detail, may also be understood as a processor. It is understood that any two (or more) of the processors detailed herein may be realized as a single entity with equivalent functionality or the like, and conversely that any single processor detailed herein may be realized as two (or more) separate entities with equivalent functionality or the like.

The term “memory” as used herein may be understood as a computer-readable medium (e.g., a non-transitory computer-readable medium), in which data or information can be stored for retrieval. References to “memory” included herein may thus be understood as referring to volatile or non-volatile memory, including random access memory (RAM), read-only memory (ROM), flash memory, solid-state storage, magnetic tape, hard disk drive, optical drive, among others, or any combination thereof. Furthermore, it is appreciated that registers, shift registers, processor registers, data buffers, among others, are also embraced herein by the term memory. It is also appreciated that a single component referred to as “memory” or “a memory” may be composed of more than one different type of memory, and thus may refer to a collective component including one or more types of memory. It is readily understood that any single memory component may be separated into multiple collectively equivalent memory components, and vice versa. Furthermore, while memory may be depicted as separate from one or more other components (such as in the drawings), it is understood that memory may be integrated within another component, such as on a common integrated chip.

Various aspects relate to sputtering at least a first element and a second element in order to deposit, on a substrate, a material layer which includes the first element and the second element in a predefined atomic ratio and/or substantially homogenous properties.

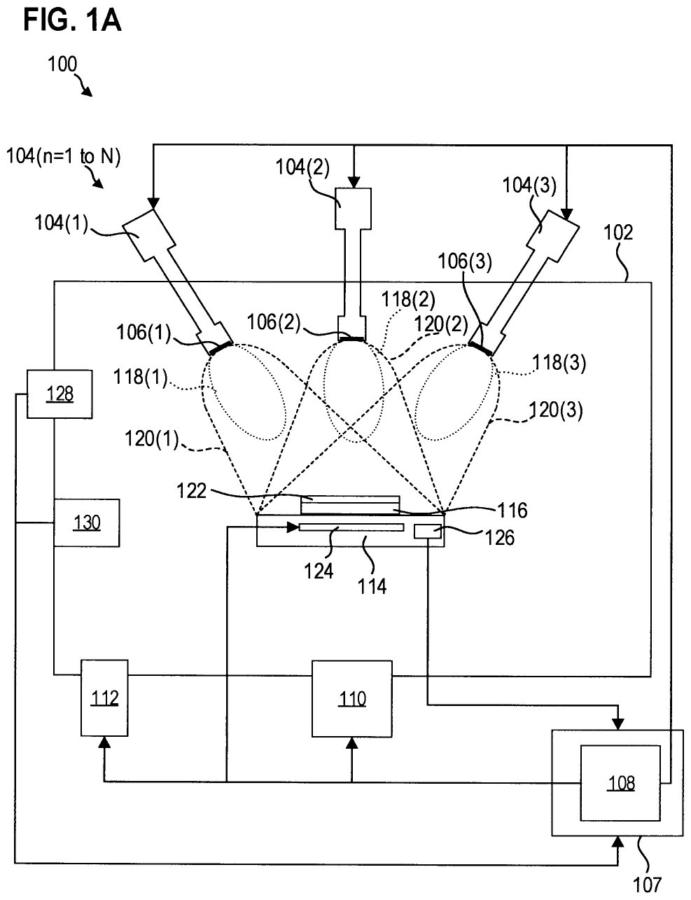

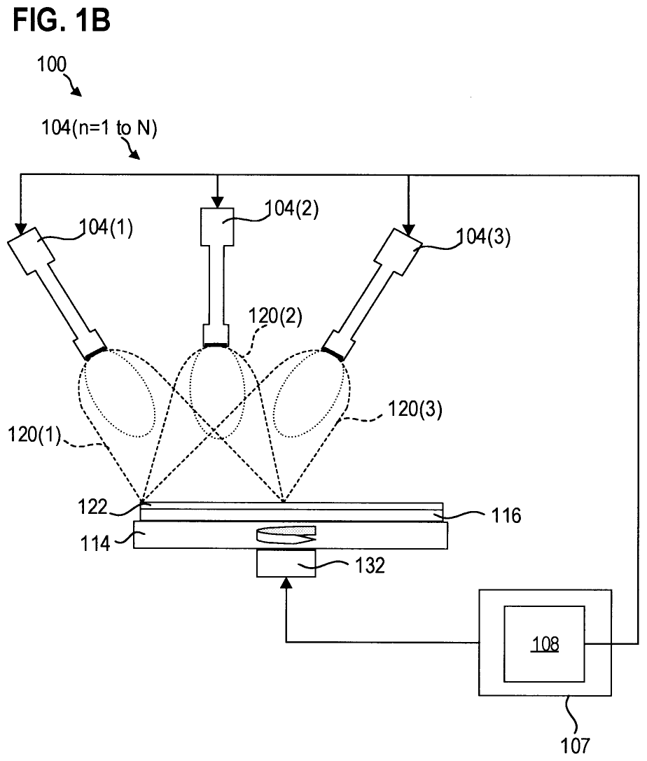

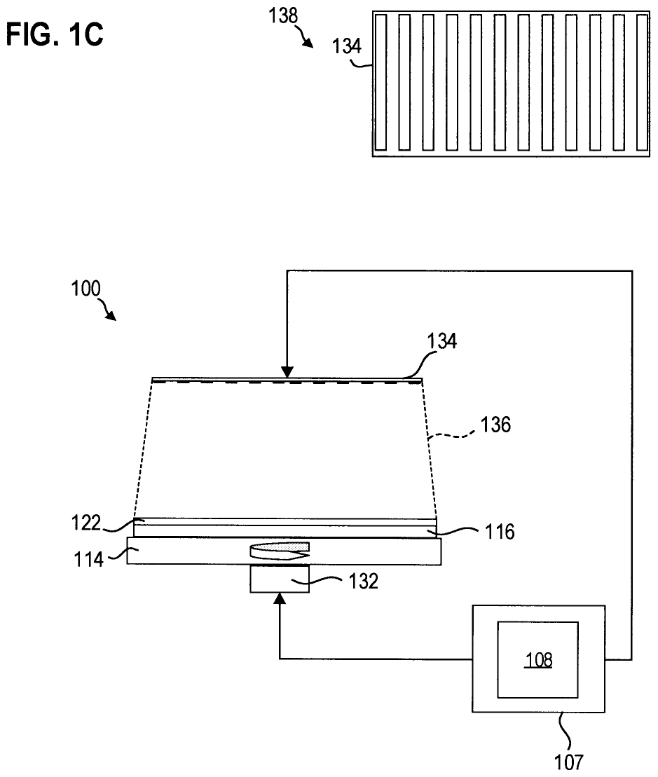

FIG. 1A shows an exemplary system 100 for sputtering at least the first element and the second element according to various aspects. The system 100 may also be referred to as sputter system and/or processing system.

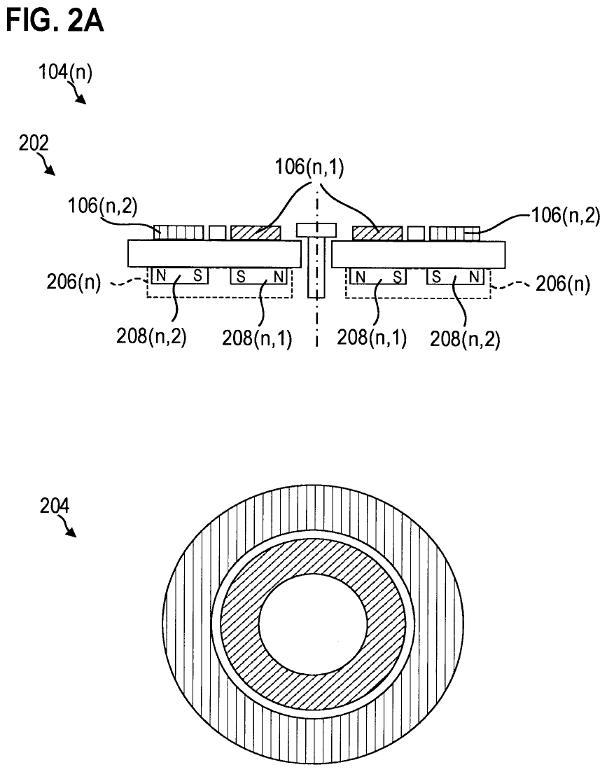

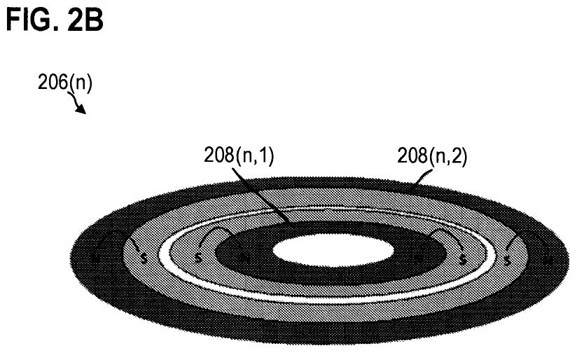

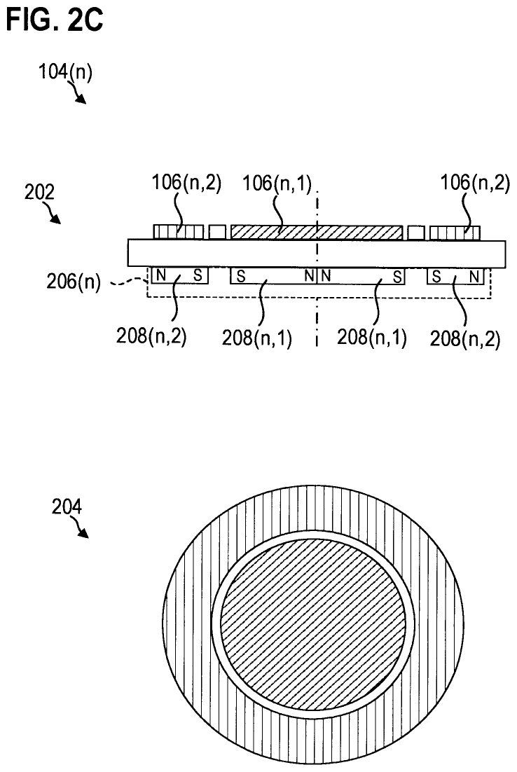

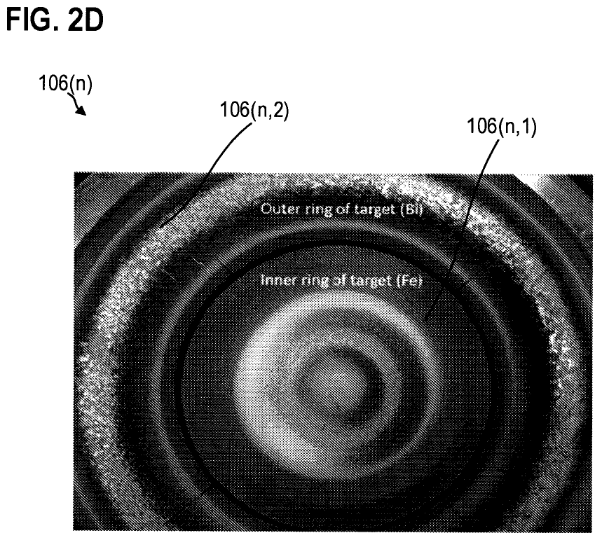

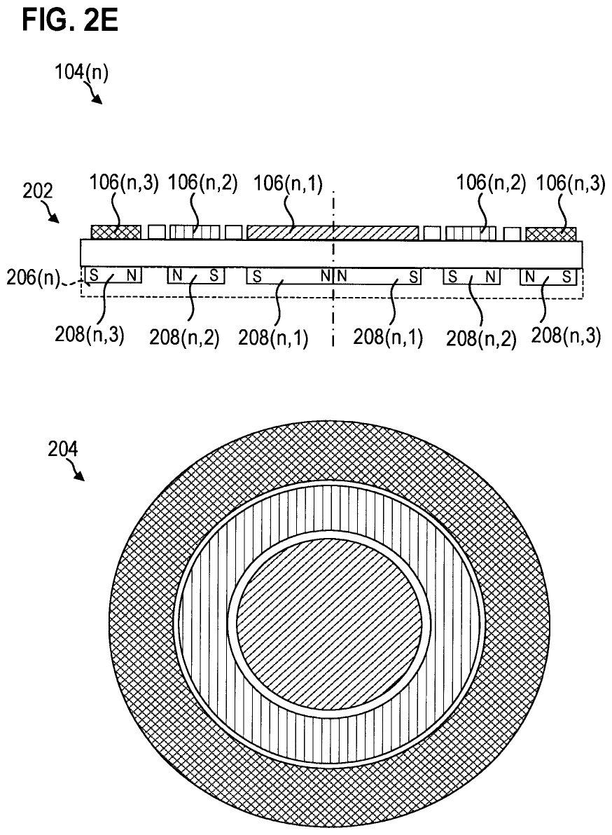

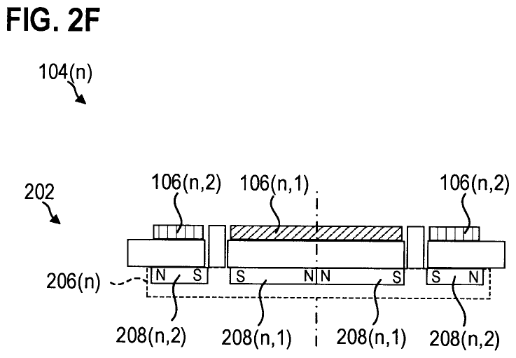

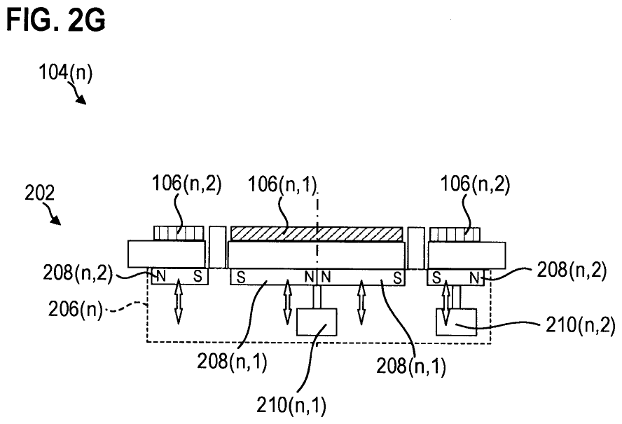

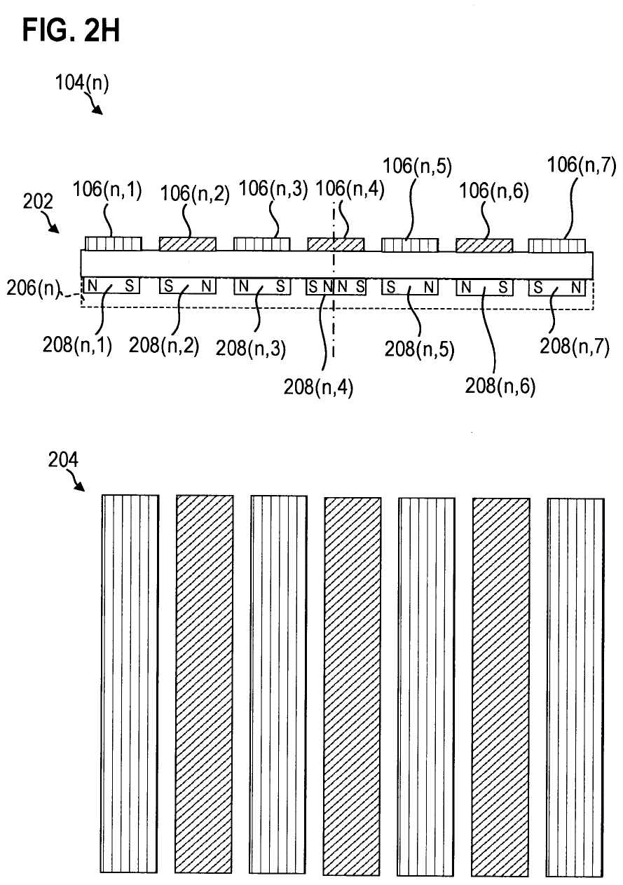

The system 100 may include a processing chamber 102 (may also be referred to as vacuum chamber). The system may include one or more sputter sources 104(n=1 to N) (with “N” being any integer number equal to or greater than one). Each sputter source 104(n) of the one or more sputter sources 104(n=1 to N) may include at least one sputter target 106(n). Each sputter target (short: target) may include one or more elements. Each (e.g., magnetron) sputter source 104(n) may be configured to (e.g., magnetron) sputter the one or more elements the corresponding at least one sputter target 106(n) includes. According to various aspects, at least one (e.g., each) sputter source of the one or more sputter sources 104(n=1 to N) may be a magnetron sputter source. It is understood that FIG. 1A and FIG. 1B show three sputter sources 104(1), 104(2), 104(3) for illustration and that, for the aspects of the disclosure as described herein, more or less sputter sources may be used. Further, it is understood that although FIG. 1A and FIG. 1B show each sputter source 104(n) to have exactly one sputter target 106(n) a sputter source may have more than one sputter target (see, for example, FIG. 2A to FIG. 2H and corresponding description). It is understood that a sputter source 104(n) may include further components, such as electronics for supplying (e.g., applying) a (e.g., high) voltage (e.g., a direct current (DC) voltage or a radio frequency (RF) voltage), a water cooling system, a shutter for blocking or releasing a deposition material stream in direction of a substrate, etc. For example, a sputter source 104(n) may be a magnetron sputter source further including one or more magnets configured to generate a magnetic field through the corresponding at least one sputter target 106(n).

The system 100 may include a control system 107. The control system 107 may include one or more controllers (a controller may also be referred to as a control device and/or may include a control device). The one or more controllers of the control system 107 may be communicatively connected to each other and/or to a main controller (e.g., a computer) configured to control the one or more controllers. Each controller of the one or more controllers may include one or more processors configured to carry out the correspondingly described processing (e.g., using a memory).

According to various aspects, the control system 107 may include a sputter controller 108. Hence, the system 100 may include the sputter controller 108. The sputter controller 108 may be configured to control the one or more sputter sources 104(n=1 to N). The sputter controller 108 may be configured to control a sputtering using the one or more sputter sources 104(n=1 to N). As described herein, a sputtering process may depend on a plurality of (static and dynamic) parameters and the sputter controller 108 may be configured to control one or more of these parameters in order to generate a material layer having predefined properties. The sputter controller 108 may include a power supply. The power supply may be configured to apply a respective (e.g., DC or RF) (high) voltage at each sputter target of the one or more sputter sources 104(n=1 to N) to sputter the one or more elements from the respective sputter target. The power supply may be configured to apply a (high) voltage to a sputter source 104(n) in accordance with a power. Although various aspects refer to applying a voltage to a sputter source 104(n), it is understood that this applies for the case that the sputter source 104(n) includes one sputter target 106(n) and that, in the case that a sputter source includes two or more sputter targets, either a same voltage may be applied to the two or more sputter targets or (see, for example, FIG. 2F and FIG. 2G) the sputter source may include electronics which allow to apply a respective voltage to each sputter target of the two or more sputter targets and the power supply may be configured to apply a respective voltage in accordance with a respective power to each of the two or more sputter targets of the sputter source. The sputter controller 108 may include a control device. The control device may be configured to control the power supply.

The system 100 may include a pump system 110. The processing chamber 102 may be coupled to the pump system 110. The pump system 110 may be configured to generate an underpressure (e.g., a vacuum) within the processing chamber 102. The pump system 110 may include one or more vacuum pumps. A vacuum pump may be any kind of vacuum pump, such as a high vacuum pump (e.g., a turbo molecular pump, TMP) or a backing pump (e.g., a scroll pump, a membrane pump, a (e.g., multistage) roots pump, a diffusion pump, a turbo molecular pump, etc.). The pump system 110 may include a combination of one or more of the above described pumps (e.g., the pump system 110 may be or may include a pump station including at least one backing pump and at least one high vacuum pump). It is understood that the processing chamber 102 may be, when closed, configured to be, for example, airtight, dust-tight, and/or vacuum-tight to achieve and/or maintain the underpressure. The control system 107 (e.g., a pump controller of the control system 107) may be configured to control the pumping system 110. An underpressure, as described herein, may be a pressure in a range from about 10 mbar to about 1 mbar (i.e., low vacuum or rough vacuum) or less, such as a pressure in a range from about 1 mbar to about 10⁻³ mbar (i.e., fine vacuum) or less, such as a pressure in a range from about 10⁻³ mbar to about 10⁻⁷ mbar (i.e., high vacuum) or less, such as a vacuum below 10⁻⁷ mbar (i.e., an ultra-high vacuum).

The system 100 may include one or more gas inlet devices 112. Each gas inlet device of the one or more gas inlet devices 112 may be coupled to a gas reservoir (e.g., a gas bottle or a gas cylinder). Each gas inlet device of the one or more gas inlet devices 112 may include or may be coupled to a mass flow controller (MFC) configured to control the mass flow of the associated gas into the processing chamber 102. According to various aspects, the control system 107 may include or may be configured to control the one or more mass flow controllers. Hence, inletting one or more gases into the vacuum within the processing chamber 102 may generate an atmosphere which includes the one or more gases in a composition depending on the respective mass flow and which has a pressure depending on the initial pressure of the vacuum and the mass flows of the one or more gases. The system 100 may include one or more pressure sensors configured to detect the pressure within the processing chamber 102 and to provide the detected pressure to the control system 107. A sputtering, as described herein, may be a non-reactive sputtering or a reactive sputtering. In the case of non-reactive sputtering, each gas of the one or more gases may be an inert gas, such as argon (Ar), helium (He), neon (Ne), krypton (Kr), xenon (Xe), etc. In the case of reactive sputtering, at least one gas of the one or more gases may be an inert gas, such as argon (Ar), and at least one further gas of the one or more gases may be a gas, such as oxygen (O₂) reacting with at least one of the sputtered elements. The control system 107 may be configured to control the respective gas flow via the one or more gas inlet devices 112 by controlling the corresponding mass flow controller (MFC). According to various aspects, the system 100 may include a mass spectrometer configured to detect a composition of the atmosphere within the processing chamber 102 to provide mass spectroscopy data representing this composition to the controls system 107. The control system 107 may be configured to control the gas flow (e.g., an oxygen gas flow) based on the mass spectroscopy data. According to various aspects, the system 100 may include an oxygen sensor (e.g., a lambda probe) configured to detect an oxygen content within the atmosphere and provide oxygen data representing this oxygen content to the control system 107. The control system 107 may be configured to determine the oxygen partial pressure based on the oxygen data and may control an oxygen flow into the processing chamber 102 based on the determined oxygen partial pressure.

The system 100 may include a sample holder 114 (in some aspects referred to as substrate holder). The sample holder 114 may be configured such that a substrate 116 can be arranged (and optionally fixed) thereon. The substrate 116 may be any kind of suitable substrate having any shape, composition, structure, etc. For example, the substrate may be a wafer (e.g., a 150 mm, 200 mm, 300 mm, or 450 mm wafer). The substrate 116 may include a material layer stack including one or more material layers of different composition. The substrate 116 may include a plurality of structures (e.g., transistors, vias, etc.). Hence, the substrate 116 may be any structural component on which the material layer 122 can be deposited.

As described herein, the sputter controller 108 may be configured to control the sputtering by the one or more sputter sources 104(n=1 to N). As understood, responsive to applying a (RF or DC) high voltage to the sputter target 106(n) inert gas ions (e.g., Ar⁺) within the atmosphere are accelerated in direction of the sputter target 106(n), thereby extracting atoms from the sputter target 106(n). Further, secondary electrons may be emitted from the sputter target 106(n) which excite the inert gas ions (e.g., Ar⁺), thereby igniting a discharge plasma 118(n). The extraction of the atoms from the sputter target 106(n) may generate a deposition material stream 120(n) in direction of the substrate 116. The atoms within the deposition material stream 120(n) may be deposited on the substrate 116, thereby (progressively) generating a material layer 122 on the substrate 116.

The system 100 may include a heating device 124 (short: heater 124). The heater 124 may be configured to heat the sample holder 114 and/or the substrate 116 to a set temperature. The heating device 124 may be or may include a resistive heater. The system 100 may include a one or more temperature sensors 126. The one or more temperature sensors 126 may be configured to detect a temperature which represents a temperature of the substrate 116 and/or the material layer 122. For example, the temperature which represents the temperature of the substrate 116 and/or the material layer 122 may be a temperature of the sample holder 114, a temperature of the heater 124, a temperature of the substrate 116, and/or a temperature of the material layer 122. According to various aspects, a temperature sensor of the one or more temperature sensors 126 may be part of the sample holder 114 and may be configured to contact the sample holder 114 or the substrate 116 to detect a temperature thereof. Additionally or alternatively, the one or more temperature sensors 126 may include at least one temperature sensor configured to contactless detect a temperature of the sample holder 114 and/or of the substrate 116 and/or of the material layer 122 (e.g., the at least one temperature sensor may be a pyrometer). The control system 107 (e.g., a heater controller) may be configured to control the heater 124 to heat the substrate 116 and/or material layer 122 to a set temperature (e.g., using the temperature detected via the one or more temperature sensors 126).

The system 100 may include one or more plasma detecting sensors 128. The one or more plasma detecting sensors 128 may be configured to detect plasma properties of at least one (e.g., each) plasma 118(n). The one or more plasma detecting sensors 128 may be configured to provide data representing the detected plasma properties to the control system 107. According to various aspects, at least one plasma detecting sensor of the one or more plasma detecting sensors 128 may be an optical sensor configured to detect plasma properties. The plasma properties may be detected using any suitable sensor and/or measurement method, such as optical emission spectroscopy (OES) (e.g., employing OES imaging), interferometry, atomic absorption spectroscopy, and/or layer-induced fluorescence, etc. The control system 107 may be configured to determine, based on the plasma properties (e.g., based on plasma emission lines and/or intensities within detected spectra), a composition of the sputtered elements within the deposition material stream. For example, the plasma properties may allow to determine an atomic ratio of the first element to the second element within the deposition material stream(s). As an example, in the case of the herein described example of (e.g., reactively) sputtering a BFO material layer, OES may be used to detect the respective intensities of the (optical) plasma emission lines of bismuth, iron, oxygen, the inert gas (e.g., argon), and optionally titanium. Various aspects described herein relate to the control system 107 being configured to carry out control aspects based on the plasma properties. Here, the control system 107 may be configured to carry out the control aspects, for example, based on the intensity (or intensities) of at least one of the (optical) plasma emission lines (e.g., more than one). For example, the control system 107 may be configured to carry out the control aspects based on a (mathematical) correlation between two or more of the intensities of the (optical) plasma emission lines. The plasma properties may include electrical properties of the plasma, such as a plasma current, a plasma voltage, a plasma power, a plasma impedance, etc. According to various aspects, the control system 107 may be configured to carry out the control aspects, for example, based on the electrical properties of the plasma.

As described herein with reference to various aspects of the disclosure, the system 100 may include one or more additional components 130 (e.g., one or more pressure sensors, a manipulator configured to control a position and/or orientation of the sample holder 114, a manipulator configured to transfer the substrate 116 into and out of the processing chamber 102, one or more gates, etc.).

As described herein, the system 100 may be in various configurations. According to various aspects, the one or more sputter sources 104(n=1 to N) may include two or more sputter sources. Sputtering at least a first (chemical) element and a second (chemical) element from two different sputter sources may be referred to as co-sputtering. According to some aspects, the two or more sputter sources and the substrate 116 may be arranged such that the two or more sputter sources have a respective focus position on the substrate 116 different from at least one other sputter source of the two or more sputter sources. According to other aspects, the two or more sputter sources and the substrate 116 may be arranged such that the two or more sputter sources have a substantially same focus position on the substrate 116. This may be referred to as confocally co-sputtering the first element and the second element. As illustrated in FIG. 1A, the focus position may be substantially a center of the substrate 116. As illustrated in FIG. 1B (showing part of the system 100), the focus position may be off-center. As an example, the substrate 116 may be a wafer and the deposition material stream may impinge on the wafer at about a middle radius of the wafer.

According to various aspects, the system 100 may include a motor 132. The motor 132 may be configured to drive the sample holder 114 to rotate (in a predefined direction). The control system 107 (e.g., a motor controller) may be configured to control the motor 132.

With reference to FIG. 1C, the system 100 may include a linear lamp array 134 (see also bottom view 138). The linear lamp array 134 may be configured to irradiate 136 in direction of the sample holder 114 to heat the material layer 122. It is understood that the processing chamber 102 may include the linear lamp array 134 in addition or alternatively to the one or more sputter sources 104(n=1 to N). According to some aspects, the linear lamp array 134 may be configured to irradiate 136 substantially the whole surface of the material layer 122. According to other aspects, the linear lamp array 134 may be configured to irradiate 136 only a portion (e.g., one half) of the surface of the material layer 122. In either case, the control system 107 may be configured to control the motor 132 to rotate the sample holder 114.

The heating device 124 may be or may include one or more resistive heaters. The one or more resistive heaters may include one or more electrically conducting lines (e.g., configured as heating spirals). The one or more electrically conducting lines of the one or more resistive heaters may be configured (e.g., arranged) such that in an inner region of the sample holder 114 (e.g., in a center portion of the sample holder 114) more heat is generated than in an outer region of the sample holder 114 (e.g., closer to an edge of the sample holder 114). For example, the one or more electrically conducting lines may be configured (e.g., arranged) such that a resistance of the one or more electrically conducting lines is larger in the outer region than in the inner region. For example, more space may be occupied by the one or more electrically conducting lines in the outer region than in the inner region. As an illustrative example, the one or more electrically conducting lines may be configures as one or more heating spirals configured (e.g., arranged) such that more heat is generated in outer windings than in inner windings of the one or more heating spirals (e.g., due to the outer windings having a higher resistance and/or more windings per area in comparison to the inner windings). Generating more heat in the outer region than in the inner region of the sample holder 114 may compensate for an enhanced cooling at an outer range of the substrate 116 (e.g., ring in the case of a wafer; the outer region of the wafer may also be referred to as edge region of the wafer), thereby increasing the homogeneity of the material layer 122. According to various aspects, the heating device 124 may be configured to generate a temperature gradient (laterally) over the sample holder 114 (e.g., increasing from a center of a wafer to the edge region of the wafer). For example, the generated heat may gradually increase from the center of the sample holder 114 to its edge. Due to an increase cooling of the edge region of the substrate 116 (e.g., wafer), the temperature gradient generated by the heating device 124 may result in a substantially stable temperature laterally over the substrate 116 (i.e., the substrate 116 having substantially no temperature gradient).

It is understood that when aspects refer to heating the substrate 116 (e.g., described exemplarily for the heating device) the heating may be carried out by the heating device 124 and/or the linear lamp array 134. For example, a temperature of the substrate 116 may depend on both, a heating via the heating device 124 and a heating via the linear lamp array 134 (which may, for example, heat one of another, or at a same time).

As described herein, a sputter source 104(n) of the one or more sputter sources 104(n=1 to N) may include at least one sputter target 106(n). FIG. 2A to FIG. 2H each shows aspects of a respective configuration of a sputter source 104(n) which includes at least two sputter targets. The figures show various cross-sectional views 202 (e.g., of rotationally symmetric aspects of the sputter source) and various top views 204.

The sputter source 104(n) may include a first target 106(n, 1) and a second target 106(n, 2). According to some aspects, the sputter source 104(n) may include more than two targets, such as the first target 106(n, 1), the second target 106(n, 2) and a third target 106(n, 3) (see, for example, FIG. 2E). The most inner target (e.g., the first target 106(n, 1)) may have an annular shape (see, for example, FIG. 2A) or a circular shape (see, for example, FIG. 2C to FIG. 2G). Each further target may have an annular shape and may be arranged concentric to the first target 106(n, 1). Hence, the second target 106(n, 2) may have an annular shape and may be arranged around and concentric to the first target 106(n, 1) (see, for example, FIG. 2A, and FIG. 2C to FIG. 2G). The third target 106(n, 3) may have an annular shape and may be arranged around and concentric to the second target 106(n, 2) (see, for example, FIG. 2E). Each target may include (e.g., may consist of) respective one or more elements. According to various aspects, the first target 106(n, 1) may include at least a first element and the second target 106(n, 2) may include at least a second element different from the first element. FIG. 2D exemplarily shows an annular second target 106(n, 2) (in this example substantially consisting of bismuth, Bi) concentrically arranged around a circular first target 106(n, 1) (in this example substantially consisting of iron, Fe). In this example, the second target 106(n, 2) includes four quarter-ring portions. As shown in FIG. 2D, a central portion of the circular first target 106(n, 1) has a substantially metallic surface whereas an outer region of the circular first target 106(n, 1) is oxidized. The annular second target 106(n, 2) shows iron oxide on an inner portion of the ring whereas the central portion of the annular second target 106(n, 2) shows metallic bismuth. This distribution may impact the composition of the deposition material stream(s) during sputtering.

The sputter source 104(n) may include a magnet system 206(n). The magnet system 206(n) may be configured to generate a first magnetic field through the first target 106(n, 1) and a second magnetic field through the second target 106(n, 2). The magnet system 206(n) may include one or more first magnets 208(n, 1) configured to generate the first magnetic field through the first target 106(n, 1). The magnet system 206(n) may include one or more second magnets 208(n, 2) configured to generate the second magnetic field through the second target 106(n, 2). In the case that the sputter source 104(n) includes more than two sputter targets, the magnet system 206(n) may respectively include one or more magnets for each sputter target of the more than two sputter targets (e.g., one or more third magnets 208(n, 3) configured to generate a third magnetic field through the third target 106(n, 3), etc.). The magnets described herein, may be permanent magnets. However, it is understood that the magnets may also be electromagnets.

According to various aspects, the one or more first magnets 208(n, 1) and/or the one or more second magnets 208(n, 2) may have an annular shape (see, for example, FIG. 2B).

According to various aspects, the first magnetic field may have a first field strength distribution different from a second field strength distribution of the second magnetic field. Similarly, the third magnetic field may have a third field strength distribution different from the first field strength distribution and/or the second field strength distribution.

According to some aspects, the first field strength distribution and/or the second field strength distribution may be preconfigured. In this case, the field strength distributions may be static. For example, the one or more first magnets 208(n, 1) may be permanent magnets having a first magnetic field strength and the one or more second magnets 208(n, 2) may be permanent magnets having a second magnetic field strength different from the first magnetic field strength. In some aspects, the one or more first magnets 208(n, 1) may have a geometry different from the one or more second magnets 208(n, 2), thereby generating a different field strength distribution. In some aspects, a number of magnets of the one or more first magnets 208(n, 1) may different from a number of magnets of the one or more second magnets 208(n, 2), thereby generating a different field strength distribution.

According to some aspects, the first field strength distribution and/or the second field strength distribution may be controlled. It is understood that there may be a combination of control and pre-configuration of the field strength distributions. The sputter source 104(n) may include a magnet control device configured to change a position and/or orientation of the one or more first magnets 208(n, 1) and/or the one or more second magnets 208(n, 2). According to some aspects, only the position and/or orientation of either the one or more first magnets 208(n, 1) or the one or more second magnets 208(n, 2) may be changeable. According to other aspects, the position and/or orientation of both, the one or more first magnets 208(n, 1) and the one or more second magnets 208(n, 2), may be changeable. For example, the sputter source 104(n) may include a first motor 210(n, 1) configured to change a distance between the one or more first magnets 208(n, 1) and the first target 106(n, 1). Additionally or alternatively, the first motor 210(n, 1) may be configured to change an orientation of the one or more first magnets 208(n, 1) relative to the first target 106(n, 1). The sputter source 104(n) may include a second motor 210(n, 2) configured to change a distance between the one or more second magnets 208(n, 2) and the second target 106(n, 2). Additionally or alternatively, the second motor 210(n, 2) may be configured to change an orientation of the one or more second magnets 208(n, 2) relative to the second target 106(n, 2). Hence, the first field strength distribution and/or the second field strength distribution may be controlled by changing a distance to or an orientation relative to the respective target. The orientation may be changed, for example, by tilting the one or more magnets.

According to some aspects, the sputter source 104(n) may be configured such that a voltage can be applied to each sputter target (e.g., the first target 106(n, 1), the second target 106(n, 2), the third target 106(n, 3), etc.) (see, for example, FIG. 2A, FIG. 2C, FIG. 2E). According to other aspects, the sputter source 104(n) may be configured such that a respective voltage can be applied to the sputter targets, such that a first voltage can be applied to the first target 106(n, 1), a second voltage can be applied to the second target 106(n, 2), a third voltage can be applied to the third target 106(n, 3), etc. (see, for example, FIG. 2F and FIG. 2G). According to various aspects, the sputter source 104(n) may be configured such that a different type of sputtering (e.g., DC sputtering (e.g., continuous DC sputtering or DC pulse sputtering) or RF sputtering) can be carried out for the different targets. For example, the sputter source 104(n) may be configured such that the first target 106(n, 1) can be RF sputtered and the second target 106(n, 2) DC sputtered (e.g., continuous DC sputtering or DC pulse sputtering), or vice versa. According to other aspects, the sputter source 104(n) may be configured such that both, the first target 106(n, 1) and the second target 106(n, 2), can be RF or DC (e.g., e.g., both continuous DC, both DC pulse, or one continuous DC and the other one DC pulse) sputtered.

In addition or alternatively to including the magnet control device for changing the position and/or orientation of the one or more first magnets 208(n, 1) and/or the one or more second magnets 208(n, 2) and/or for generating a respective magnetic field through each of the sputter targets, the sputter source 104(n) may include a target control device configured to change a position and/or orientation of the first target 106(n, 1) and/or the second target 106(n, 2) (e.g., employing one or more motors) and/or to rotate the first target 106(n, 1) and/or the second target 106(n, 2). According to some aspects, the target control device may be configured to control the position and/or orientation of the first target 106(n, 1) and/or the second target 106(n, 2) individually. According to other aspects, the target control device may be configured to the position and/or orientation of the first target 106(n, 1) and/or the second target 106(n, 2) together. This may allow to move (e.g., to toggle or wobble) and/or tilt the first target 106(n, 1) and/or the second target 106(n, 2) during sputtering, thereby increasing the homogeneity of the material layer 122. According to various aspects, such as in the case in which the sputter source 104(n) includes a plurality of (e.g., planar) stripe or stripe-like targets, the target control device may be configured to rotate the plurality of targets in-plane, thereby increasing the homogeneity of the material layer 122.

It is understood that FIG. 2A to FIG. 2G show exemplary configurations of a sputter source and that a sputter source 104(n) may include any combination of the above-described components.

According to various aspects, the first sputter target 106(n, 1) and the second sputter target 106(n, 1) may have a shape different from an annular or circular shape. For example, the first sputter target 106(n, 1) and the second sputter target 106(n, 1) may have a linear shape. Illustratively, the first sputter target 106(n, 1) and the second sputter target 106(n, 1) may be (e.g., planar) stripe or stripe-like targets. According to various aspects, the sputter source 104(n) may include a plurality of targets in an alternating sequence of targets including at least the first element and targets including at least the second element. As exemplarily shown in FIG. 2H, the sputter source 104(n) may include a first target 106(n, 1) including at least the first element, a second target 106(n, 2) including at least the second element, a third target 106(n, 3) including at least the first element, a fourth target 106(n, 4) including at least the second element, a fifth target 106(n, 5) including at least the first element, a sixth target 106(n, 6) including at least the second element, and a seventh target 106(n, 7) including at least the first element. It is understood that this serves as an example and that the sputter source 104(n) may include any number of sputter targets equal to or greater than two. Using the plurality of targets in an alternating sequence of targets including at least the first element and targets including at least the second element may allow to increase the homogeneity of the material layer 122 laterally. As described above, the target control device may be configured to rotate the plurality of targets in-plane, thereby further increasing the homogeneity of the material layer 122.

According to some aspects, the magnet system 206(n) may include one or more magnets configured to generate a magnetic field through all targets. According to other aspects, the magnet system 206(n) may include a plurality of one or more magnets with each one or more magnets being configured to generate a respective magnetic field through a corresponding target of the plurality of targets. As described above, a field strength distribution of a respective magnetic field may be controlled, such as by changing a position and/or orientation of the respective one or more magnets 208(n) (e.g., relative to the corresponding sputter target).

As described above, the sputter source 104(n) may include or may be coupled to one or more motors configured to change a position and/or orientation of the plurality of sputter targets (e.g., together or individually).

In some aspects, a same voltage may be applied to the plurality of sputter targets. In other aspects, the sputter source may include electronics which allow to apply a respective voltage to each sputter target of the plurality of sputter targets and the power supply may be configured to apply a respective voltage in accordance with a respective power to each of the plurality of sputter targets of the sputter source.

Several factors (pressure, oxygen partial pressure, power applied to a sputter source, target composition, temperature of the substrate, etc.) may impact the sputtering process. Some of these factors may vary over time. For example, the temperature of the substrate and/or deposited material layer may increase due to the atoms impinging on the substrate (may also be referred to as temperature drift). For example, the composition of the sputter target may change over time due to an inhomogeneous material distribution over depth of the sputter target and/or (e.g., in the case that the sputter target includes two or more elements) due to a selective sputtering of some elements. These factors impacting the sputtering process may consequently also impact the material layer 122 (e.g., its overall composition, its composition distribution, its electrical properties, etc.).

Various aspects relate to a (active) control of the sputtering process to generate the material layer 122 to have predefined properties (e.g., a predefined atomic ratio of two elements, substantially homogenous properties, a substantially homogeneous composition, etc.). In the following, various control aspects of the sputtering are described exemplarily for the system 100. It is understood that the control aspects may be implemented in any other system capable to sputter at least two elements using the respectively described conditions. Further, it is understood that the control aspects, as described in the following, may be, where applicable, combined with each other (e.g., a control based on a temperature may be combined with a control based on plasma properties). For illustration, various aspects are described for generating bismuth ferrite (BiFeO₃, short: BFO) material layer with predefined properties. For example, the BFO material layer be generated as part of forming one or more memristive devices. The predefined properties may be or may include predefined (e.g., analog) memristive-switching properties. For example, a plurality of memristive devices may be formed with the BFO material having substantially the predefined properties, thereby leading to homogeneous switching properties. The BFO material layer may be polycrystalline. According to various aspects, the BFO may be deposited on a wafer (as substrate 116).

According to various aspects, at least a first element (e.g., Bi) and a second element (e.g., Fe) may be sputtered using the one or more sputter sources 104(n=1 to N). It is found that, in the case that the first element has a higher temperature-dependent re-evaporation rate (e.g., from the substrate and/or from the material layer 122) than the second element, there is a characteristic temperature value which allows to generate, when setting a temperature of the substrate 116 and/or the material layer 122 equal to or greater than the characteristic temperature value, the material layer 122 to have a predefined atomic ratio between the first element and the second element. It is found that, when sputtering the first element and the second element such that their deposition material stream(s) 118(n) include an atomic ratio between the first element and the second element which is higher than the predefined atomic ratio (hence, there may be an excess of atoms of the first element) and when the temperature of the substrate 116 and/or the material layer 122 is equal to or greater than the characteristic temperature value, the material layer 122 can be generated to have the predefined atomic ratio between the first element and the second element. Due to the higher temperature-dependent re-evaporation rate, a higher number of atoms of the first element than atoms of the second element may be evaporated from the substrate 116 and/or material layer 122 at temperatures equal to or greater than the characteristic temperature value resulting in the material layer 122 to have the predefined atomic ratio. Here, atoms of the first element which are not incorporated into a (stable) phase of the material layer 122 may be evaporated from the surface of the material layer 122. The number of atoms which are evaporated from the surface may be described by the sticking coefficient which defines a ratio between a number of atoms/ions impinging on the substrate and a number of atoms/ions which remain (i.e., which are not evaporated) on the surface of the material layer.

The first element and the second element may be sputtered using a single sputter target 106(n) or using two different sputter targets mounted to a common sputter source 104(n) or mounted to two different sputter sources. According to some aspects, when using two different targets, one target of the two different targets may substantially consist of the first element and the other target of the two different targets may substantially consist of the second element. According to other aspects, when using two different targets, one target of the two different targets may include both, the first element and the second element, and the other target of the two different targets may substantially consist of either the first element or the second element.

The characteristic temperature may depend on the configuration of the system 100 (e.g., size of the processing chamber 102, arrangement of the one or more sputter sources 104(n=1 to N), gas flow within the processing chamber 102, whether a single target or two different targets are used, etc.), on the sputtering settings (e.g., a first power value of a first power used for sputtering the first element, a second power value of a second power used for sputtering the second element, an oxygen partial pressure, a mass flow, a pressure within the processing chamber 102, etc.), and on the first element and the second element (e.g., their temperature-dependent re-evaporation rate). The sputter controller 108 may be configured to control the one or more sputter sources 104(n=1 to N) to sputter the first element and the second element such the deposition material stream(s) include an atomic ratio between the first element and the second element greater than the predefined atomic ratio. The control system 107 may be configured to determine the characteristic temperature value based on the configuration of the system 100, the sputtering settings, and/or information about the first element and the second element. The control system 107 (e.g., the heater controller) may be configured to control the heater 124 to heat the substrate 116 and/or material layer 122 to have a temperature equal to or greater than the characteristic temperature value (e.g., prior to sputtering the first element and the second element).

As described, the temperature-dependent re-evaporation rate of the first element may be greater than the temperature-dependent re-evaporation rate of the second element. According to various aspects, at temperature values equal to or greater than the characteristic temperature value, the temperature-dependent re-evaporation rate of the first element may be at least twice (e.g., at least three times, such as at least four times) the temperature-dependent re-evaporation rate of the second element.

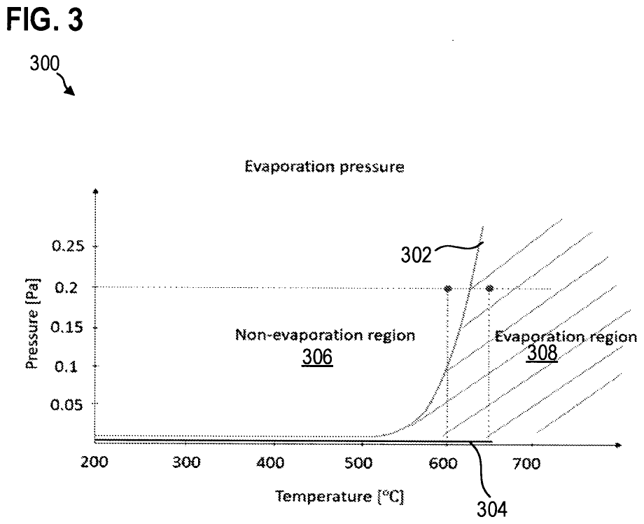

The characteristic temperature value may represent a vapor pressure (also referred to as evaporation pressure) of the first element at a (working) pressure of the atmosphere the deposition material stream is generated in. As an example, the first element may be bismuth and the second element may be iron. FIG. 3 exemplarily shows an evaporation pressure curve 302 of bismuth and an evaporation pressure curve 304 of iron. As shown, the temperature-dependent re-evaporation rate of bismuth is significantly greater than the temperature-dependent re-evaporation rate of iron. The evaporation pressure curve 302 of bismuth may, for a given (working) pressure value of the atmosphere (i.e., the pressure of the atmosphere in which the sputtering is carried out), indicate the characteristic temperature value (i.e., the temperature value corresponding to the pressure value as described by the evaporation pressure curve 302). The evaporation pressure curve 302 of bismuth may separate a non-evaporation region 306 at temperatures less than the characteristic temperature value and an evaporation region 308 at temperatures equal to or greater than the characteristic temperature value. In the non-evaporation region 306, exceeding bismuth (i.e., bismuth which is non incorporated into the (stable) phase of the material layer 122) may not be evaporated from the surface of the material layer 122 and, thus, included in the material layer 122 which leads to a bismuth concentration greater than defined by the predefined atomic ratio. In the evaporation region 308, exceeding bismuth (e.g., metallic bismuth) may be evaporated from the surface of the material layer 122, thereby allowing to generate the material layer 122 having the predefined atomic ratio. As shown in FIG. 3, compared to the evaporation pressure curve 302 of bismuth, the evaporation pressure curve 304 of iron is substantially independent of the temperature. Therefore, the atomic ratio between bismuth and iron atoms may substantially depend on the evaporation of bismuth atoms. As shown in FIG. 3, depending on the pressure of the atmosphere within the processing chamber 102 (and, as described herein, depending on the configuration of the system 100) the characteristic temperature value may be in a range from about 600° C. to about 650° C. (e.g., at about 630° C. for a working pressure of about 0.2*10⁻² mbar).

As described herein, the sputtering may be a non-reactive sputtering or a reactive sputtering. As an example, bismuth and iron may be reactively sputtered and the atmosphere may include oxygen (e.g., in addition to the inert gas). As an example, the predefined properties of the material layer 122 may include a predefined phase, such as bismuth ferrite (BiFeO₃), with a predefined atomic ratio between bismuth and iron (e.g., 1:1).

According to various aspects, there may be an upper temperature threshold value. For example, the substrate 116 may include (e.g., on its surface) a layer including a material which may, at temperatures higher than the upper temperature threshold value (unintendedly) diffuse into the material layer 122. Hence, the temperature value to which the substrate 116 and/or the material layer 122 are heated may be within a temperature range defined by a lower threshold value and the higher threshold value. The characteristic temperature value may be the lower threshold value or the lower threshold value may be determined based on the characteristic temperature value.

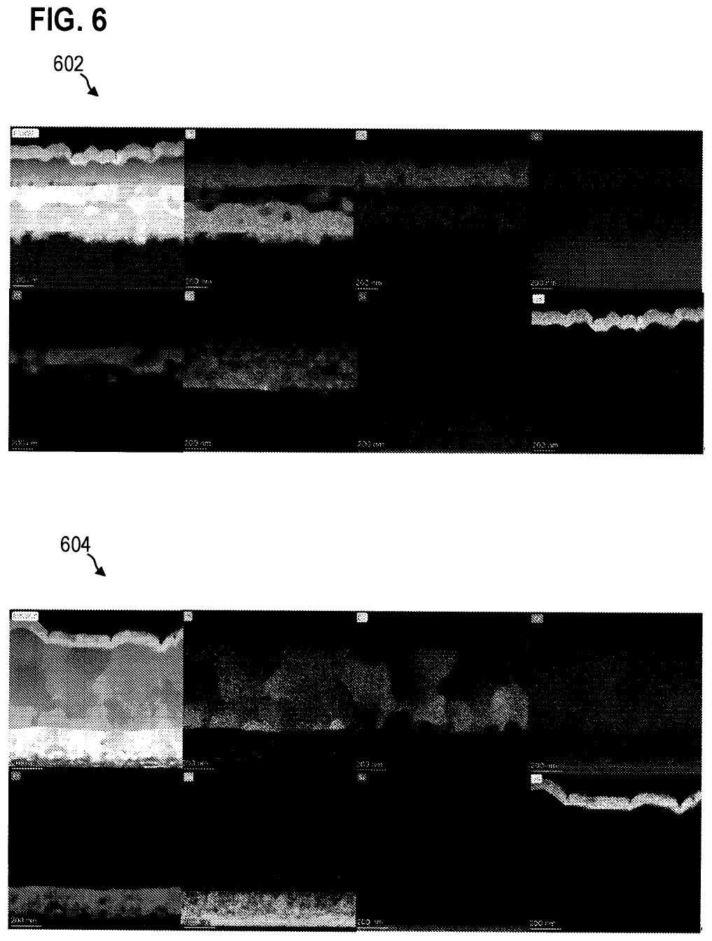

Regarding the example of depositing the BFO material layer: In the case that the BFO material layer may be deposited over a metal electrode layer (e.g., including titanium and/or platinum), temperatures greater than the upper threshold value may lead to (unintended) stress (e.g., compressive stress or tensile stress) within the metal electrode layer and/or to a (unintended) diffusion of a metal material of the metal electrode layer into the BFO material layer. FIG. 6 shows an elemental distribution of a bismuth ferrite material layer which has been sputtered on a substrate 116. Here, the substrate 116 may include a silicon wafer, a silicon oxide layer over the silicon wafer, a titanium layer over the silicon oxide layer, and a platinum layer over the titanium layer. FIG. 6 shows an elemental distribution 602 for depositing the BFO material layer at 700° C. and an elemental distribution 602 for depositing the BFO material layer at 600° C. As shown, when sputtering at 700° C., the platinum atoms of the platinum layer may diffuse into the BFO material layer. This may, for example, result in a reduced breakdown voltage of a corresponding memristive device. When sputter at 600° C. on the other hand, there is substantially no diffusion of platinum atoms into the BFO material layer. According to various aspects, an Fe₂ O₃ layer may be deposited over the platinum layer prior to depositing the BFO material layer. This may allow to slightly increase the deposition temperature (since the Fe₂ O₃ layer may serve as a diffusion barrier). As an example, the upper threshold value may have a temperature value of about 650° C. According to some aspects, a diffusion of titanium atoms of the titanium layer into the BFO material layer may be intended to generate titanium doped bismuth ferrite.

Depositing the material layer 122 at temperatures equal to or greater than the characteristic temperature may allow the material layer 122 to have a substantially homogenous stoichiometry distribution (e.g., laterally) over the whole substrate 116 (e.g., wafer) since the excess of bismuth atoms can be provided over the whole substrate 116 and the homogenous stoichiometry may be generated due to the evaporation of the excess bismuth atoms from the surface of the material layer 122.

It is understood that the principles are described exemplarily for the first element and the second element and that one or more additional elements may be sputtered (from a (e.g., the) common sputter target with at least one of the first element and/or the second element and/or from a different sputter target (using a same sputter source or a different sputter source)) using the one or more sputter sources 104(n=1 to N) to generate the material layer 122. The temperature-dependent re-evaporation rate of the one or more additional elements may be less than the temperature-dependent re-evaporation rate of the first element. For example, a third element may be sputtered having a temperature-dependent re-evaporation rate substantially similar to the temperature-dependent re-evaporation rate of the second element. In the example of the first element being bismuth and the second element being iron, the third element may be, for example, titanium (e.g., to generate titanium doped bismuth ferrite (Ti:BiFeO₃)).

However, using a sputtering temperature (i.e., a temperature of the substrate 116 and/or the material layer 122) equal to or greater than the characteristic temperature value may restrict the sputtering process to using elevated temperatures and/or to a predefined temperature range (e.g., in the case of a higher threshold value). Therefore, it may be desired to also generate the material layer 122 with predefined properties at temperatures less than the characteristic temperature value. As an example, the substrate 116 may include elements which, at temperatures equal to or greater than the characteristic temperature value, (unintendedly) diffuse into the material layer 122, whereby the predefined properties may not be achieved. As another example, the substrate 116 may include one or more components including one or more elements which may, at temperatures equal to or greater than the characteristic temperature value, (unintendedly) diffuse, thereby impairing properties of the one or more components. As an example, the substrate 116 may include a complementary metal-oxide-semiconductor (CMOS) structure including the one or more elements. Hence, the substrate 116 (e.g., wafer) may be associated with a thermal budget putting an upper limit threshold value to the temperature for sputtering the first element and the second element. Hence, in this case it may not be possible to sputter at temperatures equal to or greater than the characteristic temperature value. In the following, various control aspects are described which allow to generate the material layer 122 with the predefined properties below the characteristic temperature value. This may, for example, increase the flexibility of the sputtering process and allow to generate the material layer 122 via sputtering in the case that the substrate 116 includes one or more critical components limiting the thermal budget.

Regarding the example of depositing the BFO material layer: Allowing to deposit the BFO material layer at temperatures below the characteristic temperature may be required in order to further decrease a diffusion of platinum into the BFO material layer, thereby increasing the stability of the electrode layer (e.g., bottom electrode) and, hence, the memristive switching properties of the manufactured memristive device(s).

than the upper threshold value may lead to (unintended) stress (e.g., compressive stress or tensile stress) within the metal electrode layer and/or to a (unintended) diffusion of a metal material of the metal electrode layer into the BFO material layer.

According to various aspects, the control system 107 may be configured to (e.g., continuously) receive a temperature value representing the temperature of the substrate 116 and/or the material layer 122 via the one or more temperature sensors 126. The control system 107 may be configured to (e.g., continuously) receive, during the sputtering, the plasma properties via the one or more plasma detecting sensors 128. The sputtering process may be carried out using a plurality of operation parameters. An operation parameter of the plurality of operation parameters may be, for example, a first power value of a first power used to sputter the first element, a second power value of a second power used to sputter the second element, a power ratio between the first power and the second power, a first sputter rate with which the first element is sputtered, a second sputter rate with which the second element is sputtered, a sputter ratio between the first sputter rate and the second sputter rate, a pressure of the atmosphere within the processing chamber 102, an oxygen mass flow (e.g., set via a corresponding mass flow controller) into the processing chamber 102, the set temperature to which the heater 124 is to heat the substrate 116 and/or material layer 122, (in the case of RF sputtering) a first power frequency used to sputter the first element, a second power frequency used to sputter the second element, a frequency ratio between the first power frequency and the second power frequency, etc. The control system 107 may be configured to (e.g., continuously) control one or more operation parameters of the plurality of operation parameters based on the (received) temperature value and/or the (received) plasma properties in order to generate the material layer 122 with the predefined properties (below the characteristic temperature value). This allows to manufacture BFO material layers having predefined memristive-switching properties over the whole substrate 116 (e.g., wafer).

As described herein, the plasma properties (detected by the one or more plasma detecting sensors 128) may allow to determine a composition of the sputtered elements within the deposition material stream, such as an atomic ratio of the first element to the second element within the deposition material stream(s). According to various aspects, this composition and/or atomic ratio may change during the sputtering process (e.g., due to a thinning of at least one sputter target). The control system 107 may be configured to adapt at least one operation parameter of the one or more operation parameters in order to compensate for these changes such that the composition and/or atomic ratio may be kept substantially stable during the sputtering. For example, in the case that the control system 107 determines from the plasma properties that the atomic ratio between the first element and the second element increases, the control system 107 may be configured to control the at least one operation parameter to increase a sputter rate of the second element (e.g., by increasing the second power) and/or to decrease the sputter rate of the first element (e.g., by decreasing the first power), and vice versa. In the case of reactive sputtering, the plasma properties may indicate an oxygen content and the control system 107 may be configured to control an oxygen flow into the processing chamber 102 in the case that the oxygen content changes. According to various aspects, the control system 107 may be configured to control the oxygen flow into the processing chamber 102 based on the one or more operation parameters. For example, in the case that a power and/or a power ratio may be changed, the oxygen flow may be correspondingly changed.

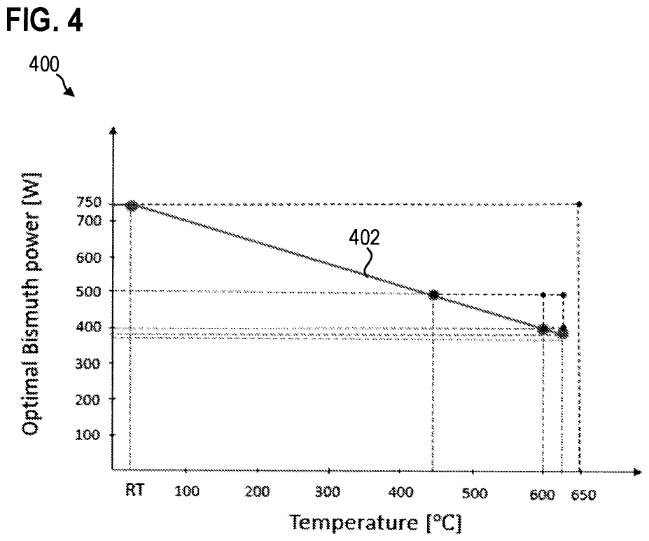

According to various aspects, the control system 107 (e.g., the sputter controller 108) may be configured to control the first power and/or the second power as an operation parameter of the one or more operation parameters. The control system 107 (e.g., the sputter controller 108) may be configured to control a power ratio between the first power and the second power as an operation parameter of the one or more operation parameters. Hence, the control system 107 may be configured to determine a power ratio (in some aspects referred to as nominal power ratio) between the first power and the second power based on the (received) temperature value and/or the (received) plasma properties and then control the first power and the second power in accordance with the determined power ratio. Thus, the first power and/or the second power (e.g., only the first power, or only the second power, or both the first power and the second power) may be changed such that the ratio between the first power and the second power (i.e., a ratio between their respective values) corresponds substantially to the determined power ratio. Regarding the example of generating a bismuth ferrite (BFO) material layer with predefined properties, FIG. 4 shows a diagram 400 illustrating (for an exemplary configuration of the system 100) a correlation 402 between the first power (i.e., the power used to sputter bismuth) and the temperature of the substrate 116 in the case that the second power (i.e., the power used to sputter iron) is set to 1000 W. Hence, the curve 402 allows to determine, for a given temperature value, a power ratio between the first power (i.e., a data point on curve 402 at the given temperature value) and the second power (i.e., 1000 W in this example). Illustratively it is shown that the power ratio may be a function of the temperature. As shown, at a temperature value of about room temperature (about 25° C.) the first power may be about 750 W (resulting in a power ratio of about 0.75), at a temperature value of about 450° C. the first power may be about 500 W (resulting in a power ratio of about 0.5), and at a temperature value of about 600° C. the first power may be about 400 W (resulting in a power ratio of about 0.4). Hence, in this example, the sputter controller 108 may be configured to control the one or more sputter sources 104(n=1 to N) to reduce the power ratio of the first power to the second power (e.g., by decreasing the first power and/or by increasing the second power) in the case that the temperature of the substrate increases and/or to increase the power ratio of the first power to the second power (e.g., by increasing the first power and/or by decreasing the second power) in the case that the temperature of the substrate decreases. As illustratively shown, a respective temperature value may be associated with a specific sputter rate ratio between a sputter rate of sputtering the first element and a sputter rate of sputtering the second element. Hence, one or more operation parameters may be adapted based on the temperature of the substrate 116 to adapt the sputter rate ratio.

Hence, both changing plasma properties and a changing temperature may be controlled by changing a sputter rate ratio. Therefore, it is understood that control aspects described based on the temperature may apply analogously to control aspects described based on the plasma properties, and vice versa.

According to various aspects, the one or more operation parameters may include the pressure of the atmosphere within the processing chamber 102. The sputter rate at which the first element is sputtered and/or the second sputter rate at which the second element is sputtered may depend on the pressure of the atmosphere. Therefore, the control system 107 may be configured to control the pressure within the processing chamber 102 (e.g., by changing a gas flow into the processing chamber 102 and/or by changing a suction power of the pump system 110 (e.g., by opening or closing a gate associated with the pumping system 110)) based on the temperature of the substrate 116 and/or based on the plasma properties (e.g., to adapt the sputter rate ratio).

As described herein, when referring to the temperature of the substrate 116 it is understood that this refers to the temperature representing the temperature of the substrate 116 (e.g., the temperature of the heater 124 and/or the temperature of the material layer 122).

According to various aspects, the control system 107 may be configured to set a temperature to which the heater 124 is to be heated and to determine the power ratio based on the set temperature prior to sputtering. Also, during sputtering the control system 107 may continuously receive the temperature detected by the one or more temperature sensors 126 and may determine a power ratio based on the temperature and then control the first power and/or the second power in accordance with the power ratio.

According to various aspects, the first element may be radio frequency (RF) sputtered in accordance with a first frequency and the second element may be radio frequency (RF) sputtered in accordance with a second frequency. The control system 107 (e.g., the sputter controller 108) may be configured to control the first frequency and/or the second frequency as an operation parameter of the one or more operation parameters. The control system 107 (e.g., the sputter controller 108) may be configured to control a frequency ratio between the first frequency and the second frequency as an operation parameter of the one or more operation parameters. Hence, the control system 107 may be configured to determine a frequency ratio (in some aspects referred to as nominal frequency ratio) between the first frequency and the second frequency based on the (received) temperature value and/or the (received) plasma properties and then control the first frequency and/or the second frequency in accordance with the determined frequency ratio.

According to various aspects, the first element may be DC pulse sputtered and the second element may be DC pulse sputtered. The control system 107 (e.g., the sputter controller 108) may be configured to control first pulse properties (a pulse duration, a pulse rate, and/or a pulse power) of the pulses associated with DC pulse sputtering the first element and/or to control second pulse properties (a pulse duration, a pulse rate, and/or a pulse power) of the pulses associated with DC pulse sputtering the second element as operation parameters of the one or more operation parameters. The control system 107 (e.g., the sputter controller 108) may be configured to control a ratio between the first pulse properties and the second pulse properties (e.g., a ratio between the pulse durations, a ratio between the pulse rates, a ratio between the pulse powers, etc.) as an operation parameter of the one or more operation parameters. The control system 107 may be configured to determine the ratio based on the (received) temperature value and/or the (received) plasma properties and then control the first pulse properties and/or the second pulse properties in accordance with the determined ratio.

According to various aspects, the system 100 may include a surface roughness sensor (e.g., an optical roughness sensor) configured to detect a surface roughness of the material layer 122 (e.g., during deposition). The surface roughness may depend on a stoichiometry (e.g., the atomic ratio between the first element and the second element). The surface roughness sensor may be configured to provide roughness data representing the detected surface roughness to the control system 107. The control system 107 may be configured to determine the one or more operation parameters based on the surface roughness. For example, in the case that the roughness data indicate that the atomic ratio falls below the predefined atomic ratio, the control system 107 may be configured to control the one or more sputter sources based on adapted one or more operation parameters to adapt at least one sputter rate to increase the atomic ratio, and vice versa.

As described with reference to FIG. 2A to FIG. 2G, a (magnetron) sputter source 104(n) of the one or more sputter sources 104(n=1 to N) may be configured to allow a control of the first magnetic field and/or the second magnetic field. It is understood that also a sputter source 104(n) having a single target may include a magnet system which allows to control the magnetic field through the single target. According to various aspects, the control system 107 (e.g., the sputter controller 108) may be configured to control the first magnetic field associated with sputtering the first element and/or the second magnetic field associated with sputtering the second element as an operation parameter of the one or more operation parameters. The control system 107 (e.g., the sputter controller 108) may be configured to control a field ratio between the first magnetic field and the second magnetic field as an operation parameter of the one or more operation parameters. Adapting the first magnetic field and/or the second magnetic field may change the composition of the deposition material stream(s) and, thus the atomic ratio between the first element and the second element. The control system 107 may be configured to control the first magnetic field and/or the second magnetic field based on the plasma properties (e.g., to adapt the sputter rate of at least one of the first element and second element) and/or based on the temperature of the substrate (e.g., since a different temperature may require a different (e.g., optimal) sputter rate). As described herein, a magnetic field may be changed by controlling the corresponding one or more magnets to change a distance between the one or more magnets and the corresponding sputter target and/or to change an orientation relative to the corresponding sputter target (e.g., by tilting the one or more magnets). As an example, the field ratio between the first magnetic field and the second magnetic field may be controlled by controlling a distance ratio between the first distance of the one or more first magnets to the first target and the second distance of the one or more second magnets to the second target. In the example of depositing the BFO material layer, the first magnetic field through the target including bismuth may have a first magnetic field strength and the second magnetic field through the target including iron may have a first magnetic field strength greater than the second magnetic field strength.

It is understood that the control system 107 may be configured to control the one or more operation parameters based on both, the temperature of the substrate and the plasma properties. For example, the control system 107 may be configured to control the one or more operation parameters using a first control loop and a second control loop. Within the first control loop, the control system 107 may adapt at least one operation parameter of the one or more operation parameters based on the temperature of the substrate (e.g., by controlling the power ratio as illustratively shown in FIG. 4). Within the second control loop, the control system 107 may adapt at least one operation parameter of the one or more operation parameters based on the plasma properties. According to various aspects, a first cycle of the first control loop may be different from a second cycle of the second control loop. The first cycle may indicate a first time interval at which the operation parameters are adapted and the second cycle may indicate a second time interval at which the operation parameters are adapted. As described herein, the temperature of the substrate may be set to the heater 124 and may change (slightly) due to a temperature drift induced by impinging atoms. Therefore, the rate at which the one or more operation parameter are adapted may be less than the rate of the second cycle (i.e., in a given time period the one or more operation parameters may be adapted more often based on the plasma properties than on the temperature of the substrate). For example, the one or more operation parameters may be adapted every 2 seconds based on the plasma properties and every 20 seconds based on the temperature of the substrate.

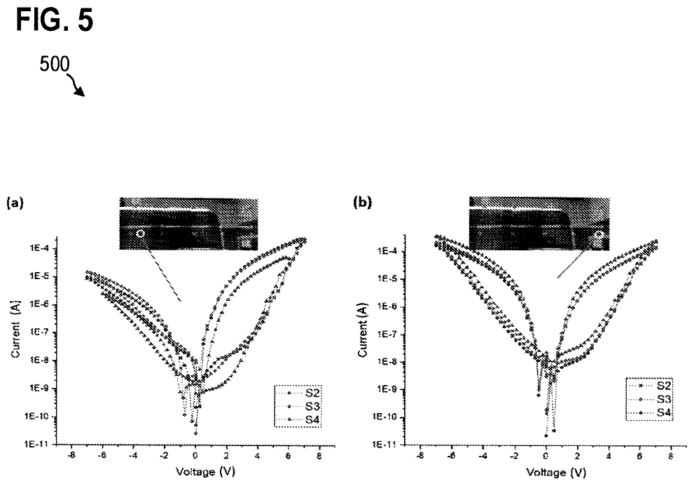

When depositing, via sputtering, a material layer on a substrate (e.g., a wafer) having a lateral size greater than a predefined threshold value, properties of the material layer may vary laterally. For example, a stoichiometry of the material layer 122 may vary laterally on the substrate 116. FIG. 5 exemplarily shows current-voltage characteristics of memristive devices which include a sputtered bismuth ferrite material layer. Diagram a) shows memristive switching properties for different memristive devices S2, S3, S4 at a first wafer position, and diagram b) shows memristive switching properties for different memristive devices S2, S3, S4 at a second wafer position different from the first wafer position. As shown, the memristive switching properties (the current-voltage characteristics) of the memristive devices may vary depending on the lateral position on the wafer. Here, the memristive devices at the first wafer position show a hysteresis only at positive voltages, whereas the memristive devices at the second wafer position show a respective hysteresis at both positive and negative voltages.

According to various aspects, the material layer 122 may be deposited using a configuration of the system 100 which includes the motor 132 to rotate the sample holder 114 and in which the one or more sputter sources are focused off-center (having a same or different foci) (see, for example, FIG. 1B). As an example, the first target 106(1) of the first sputter source 104(1) may include the first element and the second element and the focus of the first sputter source 104(1) may be off-center on the substrate 116. As another example, the first sputter source 104(n) may include the first target 106(1,1) including (e.g., substantially consisting of) the first element and another target 106(1,2) including (e.g., substantially consisting of) the second element and the focus of the first sputter source 104(1) may be off-center on the substrate 116. As an even further example, the first target 106(1) of the first sputter source 104(1) may include the first element and the second target 106(2) of the second sputter source 104(2) may include the second element, and the first sputter source 104(1) may have a first focus off-center on the substrate 116 and the second sputter source 104(2) may have a second focus off-center on the substrate 116. The second focus may correspond to the first focus (in the case of confocally co-sputtering the first element and the second element) or the second focus may be different from the first focus. According to various aspects, the substrate 116 may be a wafer and the first focus and/or the second focus may be on a position at about half radius of the wafer.

The control system 107 (e.g., the motor controller) may be configured to rotate the sample holder 114 with a rotation speed (may also be referred to as rotation frequency) equal to or greater than a predefined rotation speed. The predefined rotation speed may indicate that in one rotation (e.g., revolution) of the substrate 116 a partial layer of the material layer 122 is formed with a thickness of about a lattice constant of a crystal structure associated with a predefined phase of the material layer 122. This may allow to generate memristive devices which have substantially homogenous properties (laterally) over the whole substrate 116. It is found that in the case that the rotation (e.g., revolution) of the substrate 116 is less than the predefined rotation speed, diffusion processes may lead to a generation of other phases than a predefined phase of the predefined properties. Hence, the predefined rotation speed may depend on the deposition rate at which the material layer 122 is deposited. The control system 107 may be configured to determine the predefined rotation speed based on the deposition rate. According to various aspects, the control system 107 may be configured to determine the predefined rotation speed as a function of the deposition rate. As described herein, the control system 107 may be configured to control one or more operation parameters of the sputtering process and may adapt them during sputtering. Hence, when adapting one or more operation parameters to, for example, adapt the sputter rate of the first element and/or the sputter rate of the second element, the deposition rate may change. Therefore, the control system 107 may be configured to also adapt the predefined rotation speed (may also be referred to as predefined rotation speed value) based on the one or more operation parameters. According to various aspects, the control system 107 may be configured to determine a rotation speed value equal to or greater than the predefined rotation speed (value) and may control the motor 132 to rotate the substrate 116 in accordance with the determined rotation speed value. Further, the diffusion processes may depend on the temperature of the material layer 122. Therefore, the predefined rotation speed (value) may also depend on the temperature of the material layer 122. Thus, the control system 107 may be configured to also adapt the predefined rotation speed (value) based on a temperature representing the temperature of the material layer 122 (e.g., the temperature of the substrate 116). As described herein, the temperature of the substrate 116 may vary during depositing the material layer 122.

In an example: The control system 107 may determine the predefined rotation speed prior to the sputtering and may control the motor 132 to rotate the substrate 116 with a rotation speed equal to or greater than the predefined rotation speed (value). During deposition, the control system 107 may adapt the one or more operation parameters based on the temperature of the substrate 116 (and optionally further based on the plasma properties) (as described herein). This adaption of the one or more operation parameters may change the sputter rate of the first element and/or the second element and, thus, the deposition rate. Therefore, the control system 107 may also adapt the predefined rotation speed based on the one or more operation parameters (in accordance with the changed deposition rate) and, since the temperature of the substrate 116 also changes the diffusion processes, also based on the temperature of the substrate 116.

According to various aspects, the rotation speed may be greater than 60 revolutions per minute.

The deposition rate may have a lower threshold value corresponding to a minimal required power to sputter the respective element from the corresponding power. Therefore, the deposition rate cannot be reduced to a value less than the lower threshold value. This implies at the same time, that there may be a lower value for the predefined rotation speed. Therefore, it may be required to configure the system 100 to allow a rotation speed to be as high as possible, thereby allowing a broader range of deposition rates.

In the example of depositing the BFO material layer (i.e., having bismuth ferrite as predefined phase), the lattice constant of bismuth ferrite (BiFeO₃) is about 0.563 nm. The control system 107 may be configured to determine the predefined rotation speed (value) such that in one rotation (e.g., revolution) of the substrate 116, for a specific (e.g., current) deposition rate, a layer of about 0.563 nm is formed and may then determine a rotation speed value equal to or greater than the determined predefined rotation speed (value).

As described herein, in the case that the rotation (e.g., revolution) of the substrate 116 is less than the predefined rotation speed, diffusion processes may lead to a generation of other phases than the predefined phase (e.g., BFO). These other phases may have a lattice constant different from the predefined phase. According to various aspects, the control system 107 may be configured to determine the predefined rotation speed also based on the lattice constants of the other (possible) phases. Hence, the control system 107 may consider the phase having a lowest lattice constant. The control system 107 may be configured to determine the predefined rotation speed to indicate that in one rotation (e.g., revolution) of the substrate 116 a partial layer of the material layer 122 is formed with a thickness of about a lattice constant of a crystal structure associated with a (possible) phase of the material layer 122 (with the (possible) phase having a lowest lattice constant of the (possible) phases of the material layer 122). In the example of depositing the BFO material layer (i.e., having bismuth ferrite as predefined phase), the lattice constant of bismuth oxide (Bi₂O₃) (as possible phase) is about 0.566 nm and the lattice constant of iron oxide (Fe₂O₃) (as possible phase) is about 0.84 nm. Therefore, in this example, the lattice constant of BFO may be the lowest lattice constant of the possible phases. This may prohibit that a monolayer of bismuth oxide or iron oxide is formed. For example, at temperatures of about 650° C. these monolayers may be stable prohibiting to generate the predefined BFO phase.

According to various aspects, the material layer 122 may be irradiated during and/or after the sputtering using the linear lamp array 134. The control system 107 may be configured to control the motor 132 to rotate the sample holder 114 in accordance with a set rotation speed during the irradiation. It is found that, due to the linear arrangement of the lamps, the irradiated (e.g., temperature-treated) material layer 122 may have inhomogeneous properties (e.g., between region located direction below the lamps and region located between two neighboring lamps) and that rotating the material layer 122 (e.g., by rotating the sample holder 132) results in substantially homogenous properties laterally along the material layer 122.

As described herein, the first element and the second (and optionally the third element and/or oxygen) may be sputtered from common targets and/or from different targets, and in the case of different targets, they may be mounted to a same sputter source or to different sputter sources. Further, in the case that a sputter target includes one of the elements, it is understood that the sputter target may further include other elements. It is also understood that the first element and the second element may be sputtered from a common target and at the same time the first element and/or the second element may be sputtered from a further sputter source(s). The control aspects described herein may be applicable to any of these configurations if not explicitly stated otherwise. In the following, various exemplary sputtering scenarios are described for the example of depositing the BFO material layer:

According to various aspects, bismuth and iron may be sputtered reactively (i.e., in an oxygen atmosphere) to generate the BFO material layer. According to some aspects, bismuth and iron may be sputtered from a common target. According to other aspects, bismuth and iron may be sputtered from two different targets (mounted to a same sputter source or to different sputter sources). Bismuth may be sputtered from a first target and iron may be sputtered from a second target. In some aspects, the first target may substantially consist of bismuth and the second target may substantially consist of iron.

Sputtering two or more elements (e.g., from two different targets) at the same time may be referred to as co-sputtering the two or more elements.

According to various aspects, bismuth, iron, and oxygen may be sputtered to generate the BFO material layer (e.g., non-reactively). Again, any suitable configuration of sputter target(s) may be used. As an example, bismuth, iron, and oxygen may be sputtered from a common BFO target (e.g., including an atomic ratio between bismuth and iron greater than the predefined atomic ratio). As an alternative to the common target or in addition to the common target, bismuth may be sputtered from a first target and iron may be sputtered from a second target (different from the first target). In this case, the first target and/or the second target may further include oxygen (e.g., the first target may be a bismuth oxide target and/or the second target may be an iron oxide target).

As described herein, further elements may be sputtered, such as the third element. As an example, the third element may be titanium (Ti). In this case, the BFO material layer may be a titanium doped BFO material layer (Ti:BiFeO₃). The titanium doped BFO material layer may be deposited reactively or non-reactively as described herein. In either case, at least one sputter target may include titanium. In some aspects, titanium may be sputtered from a titanium sputter target (i.e., a target substantially consisting of titanium) or a titanium oxide sputter target (i.e., a target substantially consisting of titanium oxide). In this case, the control system 107 may be configured to control the sputtering of titanium such that the sputter target burns continuously and a shutter corresponding to the sputter source to which the sputter targets is mounted may be opened/closed to control a titanium content within the deposition material stream. As an alternative or in addition to the titanium sputter target, at least one of the other sputter targets may include titanium. For example, the common BFO target may include titanium (e.g., may be a titanium doped BFO target). For example, one or more of: a bismuth target (i.e., a target substantially consisting of (metallic) bismuth), an iron target (i.e., a target substantially consisting of (metallic) iron), a bismuth oxide (i.e., a target substantially consisting of bismuth oxide), and/or an iron oxide (i.e., a target substantially consisting of iron oxide), etc. may include titanium.

Various aspects relate to control aspects based on the temperature of the substrate 116 and/or the plasma properties. When adapting one or more operation parameters of the sputtering, sputtering rates of the first element (e.g., Bi) and/or the second element (e.g., Fe) may change resulting in a change of the composition of the deposition material stream(s). Therefore, the control system 107 may be configured to also adapt one or more operation parameters associated with sputtering the third element (e.g., Ti) in order to generate the material layer 122 (e.g., the BFO material layer) to have a predefined concentration of the third element (e.g., Ti).

According to various aspects, the substrate 116 may include a complementary metal-oxide-semiconductor (CMOS) structure and a metallization structure (e.g., including one or more metallization layers) over the CMOS structure. The system 100 may be configured to form at least part of one or more memristive devices over the metallization structure. For example, the system 100 an electrode layer over the metallization structure or the substrate 116 may already include the electrode layer. As an example, the electrode layer may include a platinum layer and a titanium layer. The system 100 may be configured to deposit the BFO material layer 122 (having predefined memristive properties) over the electrode layer (using any kind of deposition described herein).

The CMOS structure may have a thermal budget allowing only temperatures below the characteristic temperature value. Using one or more of the control aspects described herein, the material layer 122 can be generated with the predefined properties even at temperatures below the characteristic temperature value. These temperatures may not allow to generate a titanium doped BFO material layer via a diffusion of titanium into the BFO material layer. Therefore, titanium may be sputtered as described herein to generate the titanium doped BFO material layer with predefined properties (e.g., having the predefined titanium concentration).

According to various aspects, the system 100 may be configured to form a metal layer over the metallization layer prior to forming the one or more memristive devices or the substrate 116 may already include the metal layer. The metal layer may be configured such that, when, during and/or after forming the material layer (e.g., the BFO material layer), the material layer 122 is irradiated using the linear lamp array (e.g., in combination with rotating the substrate holder 114), the metal layer reflects at least 70% (e.g., at least 90%) of incident radiation from the linear lamp array. Hence, the metal layer may be configured as a reflective layer. For example, the metal layer may include or may substantially consist of a noble metal). This may allow to increase the homogeneity of the material layer 122 after irradiation (e.g., after thermal treatment). Optionally, a non-reflective layer (e.g., a layer reflects at least 10% (e.g., at least 5%) of incident radiation) may be arranged below the metal layer.

In the following, various exemplary methods are described for generating a material layer (e.g., a BFO material layer) having predefined properties. It is understood that these methods serve for illustration and that features thereof may be combined with each other, where applicable. The methods may be carried out using the system 100.

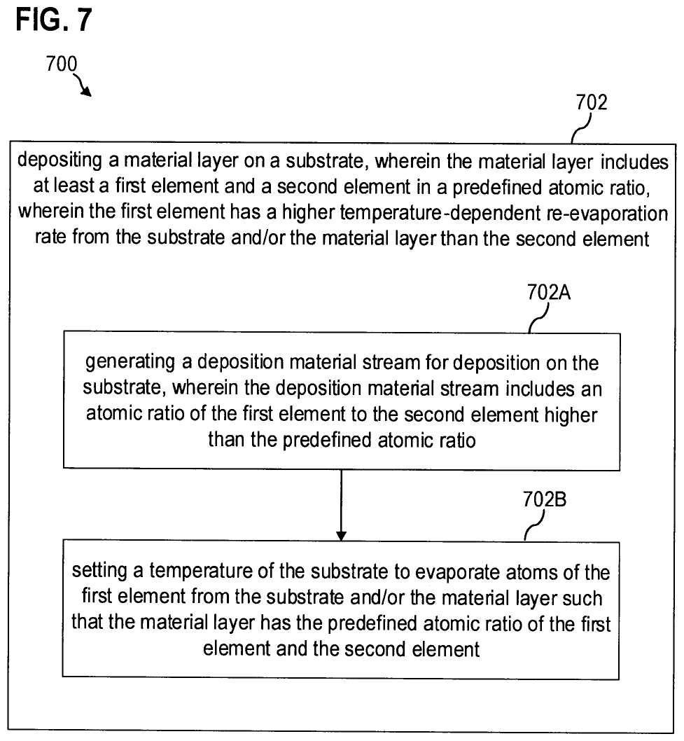

FIG. 7 shows a flow diagram of a method 700 for deposition a material layer which includes at least a first element and a second element in a predefined atomic ratio.

The method 700 may include depositing a material layer on a substrate (in 702). The material layer may include at least a first element and a second element in a predefined atomic ratio. The first element may have a higher temperature-dependent re-evaporation rate from the substrate and/or the material layer than the second element.

Depositing the material layer on the substrate (in 702) may include generating a deposition material stream for deposition on the substrate (in 702A). The deposition material stream may include an atomic ratio of the first element to the second element higher than the predefined atomic ratio.

Depositing the material layer on the substrate (in 702) may include setting a temperature of the substrate to evaporate atoms of the first element from the substrate and/or the material layer such that the material layer has the predefined atomic ratio of the first element and the second element (in 702B).

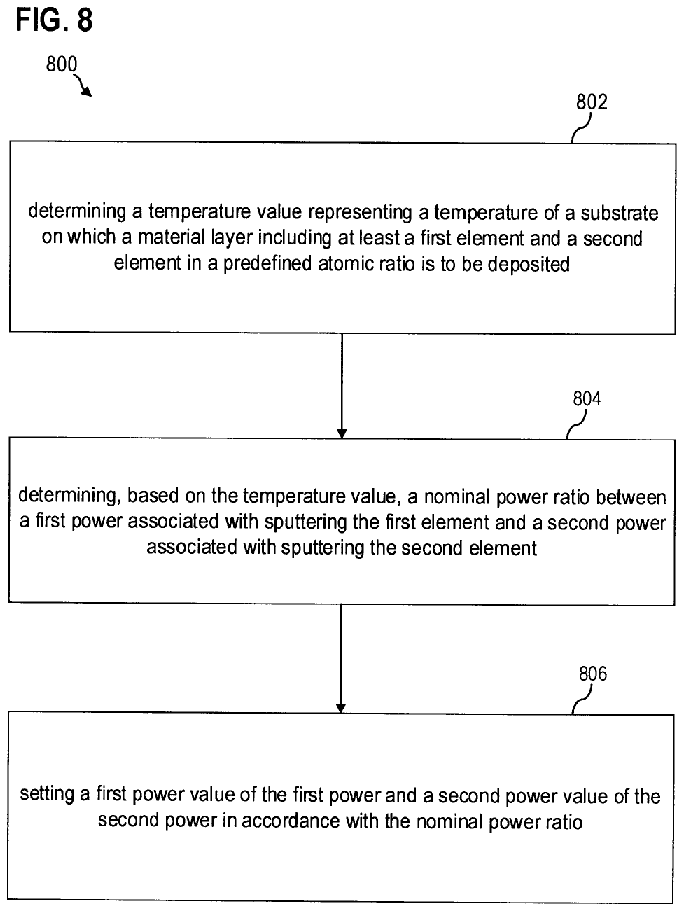

FIG. 8 shows a flow diagram of a method 800 for setting (e.g., controlling) one or more operation parameters of a sputtering process.

The method 800 may include determining a temperature value representing a temperature of a substrate on which a material layer including at least a first element and a second element in a predefined atomic ratio is to be deposited (in 802).

The method 800 may include determining, based on the temperature value, a nominal power ratio between a first power associated with sputtering the first element and a second power associated with sputtering the second element (in 804).

The method 800 may include setting a first power value of the first power and a second power value of the second power in accordance with the nominal power ratio (in 806).

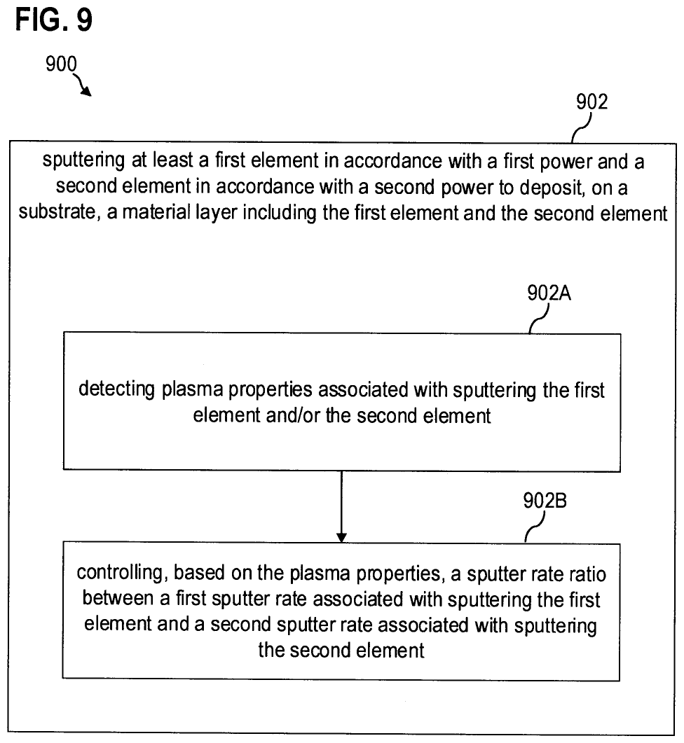

FIG. 9 shows a flow diagram of a method 900 for controlling one or more operation parameters of a sputtering process.

The method 900 may include sputtering at least a first element in accordance with a first power and a second element in accordance with a second power to deposit, on a substrate, a material layer including the first element and the second element (in 902).

The method 900 may include, during the sputtering (in 902), detecting plasma properties associated with sputtering the first element and/or the second element (in 902A).

The method 900 may include, during the sputtering (in 902), controlling, based on the plasma properties, a sputter rate ratio between a first sputter rate associated with sputtering the first element and a second sputter rate associated with sputtering the second element (in 902B).

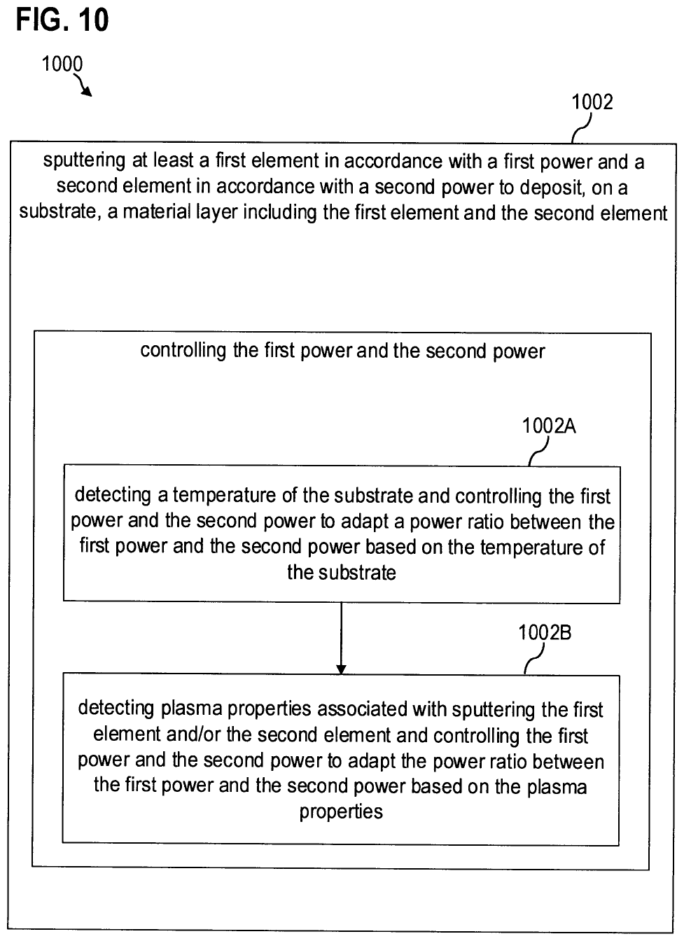

FIG. 10 shows a flow diagram of a dual loop control method 1000 for controlling one or more operation parameters of a sputtering process.

The dual loop control method 1000 may include sputtering at least a first element in accordance with a first power and a second element in accordance with a second power to deposit, on a substrate, a material layer including the first element and the second element (in 1002).

The dual loop control method 1000 may include, during sputtering the first element and the second element (in 1002), controlling the first power and the second power via a first control loop (in 1002A) and a second control loop (in 1002B). The first control loop may (in 1002A) include detecting a temperature of the substrate and controlling the first power and the second power to adapt a power ratio between the first power and the second power based on the temperature of the substrate. The second control loop may (in 1002B) include detecting plasma properties associated with sputtering the first element and/or the second element and controlling the first power and the second power to adapt the power ratio between the first power and the second power based on the plasma properties.

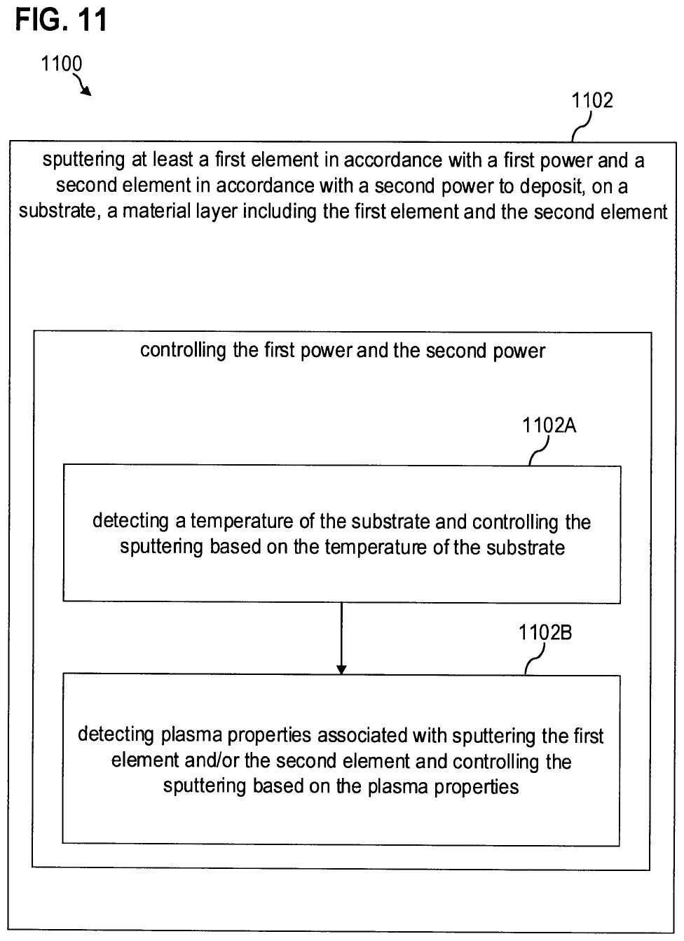

FIG. 11 shows a flow diagram of a dual loop control method 1100 for controlling one or more operation parameters of a sputtering process.

The dual loop control method 1100 may include sputtering at least a first element in accordance with a first power and a second element in accordance with a second power to deposit, on a substrate, a material layer including the first element and the second element (in 1102).

The dual loop control method 1100 may include, during sputtering the first element and the second element (in 1102), controlling the first power and the second power via a first control loop (in 1102A) and a second control loop (in 1102B). The first control loop may (in 1102A) include detecting a temperature of the substrate and controlling the sputtering based on the temperature of the substrate. The second control loop may (in 1002B) include detecting plasma properties associated with sputtering the first element and/or the second element and controlling the sputtering based on the plasma properties.

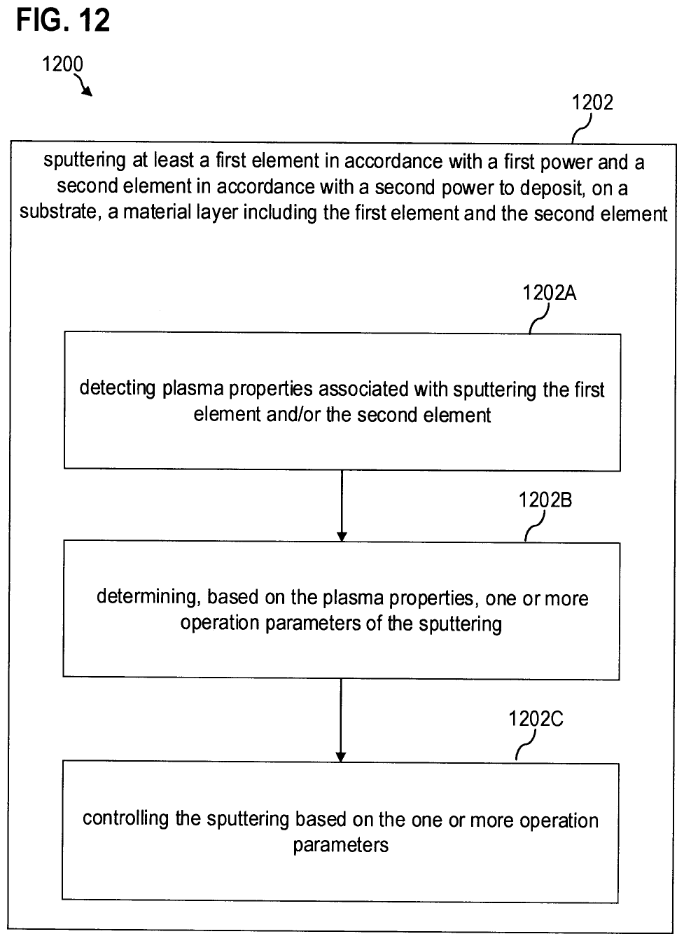

FIG. 12 shows a flow diagram of a method 1200 for controlling one or more operation parameters of a sputtering process.

The method 1200 may include sputtering at least a first element in accordance with a first power and a second element in accordance with a second power to deposit, on a substrate, a material layer including the first element and the second element (in 1202).

The method 1200 may include, during the sputtering (in 1202), detecting plasma properties associated with sputtering the first element and/or the second element (in 1202A).

The method 1200 may include, during the sputtering (in 1202), determining, based on the plasma properties, one or more operation parameters of the sputtering (in 1202B).

The method 1200 may include, during the sputtering (in 1202), controlling the sputtering based on the one or more operation parameters (in 1202C).

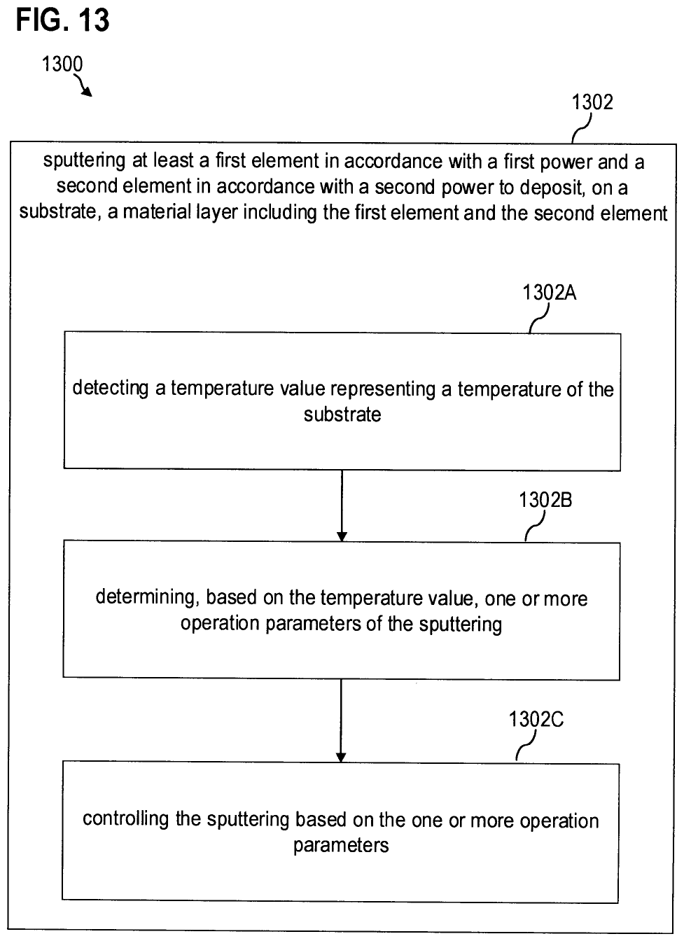

FIG. 13 shows a flow diagram of a method 1300 for controlling one or more operation parameters of a sputtering process.

The method 1300 may include sputtering at least a first element in accordance with a first power and a second element in accordance with a second power to deposit, on a substrate, a material layer including the first element and the second element (in 1302).

The method 1300 may include, during the sputtering (in 1302), detecting a temperature value representing a temperature of the substrate (in 1302A).

The method 1300 may include, during the sputtering (in 1302), determining, based on the temperature value, one or more operation parameters of the sputtering (in 1302B).

The method 1300 may include, during the sputtering (in 1302), controlling the sputtering based on the one or more operation parameters (in 1302C).

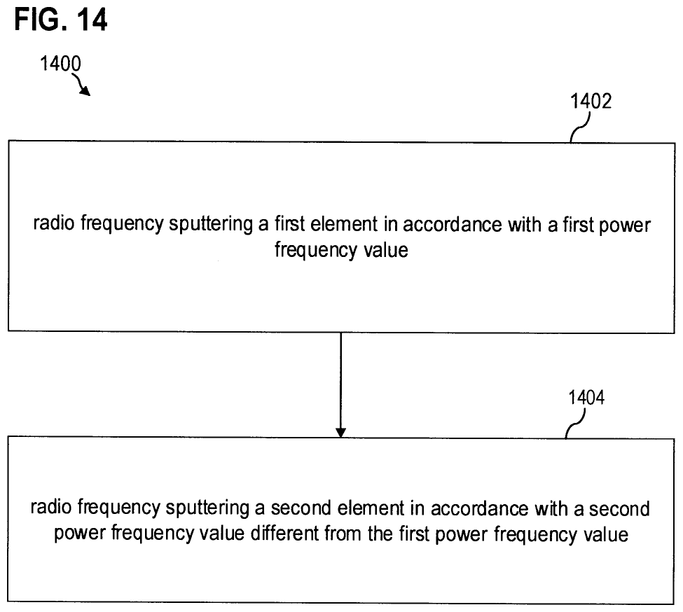

FIG. 14 shows a flow diagram of a method 1400 for controlling a sputtering process.

The method 1400 may include radio frequency sputtering a first element in accordance with a first power frequency value (in 1402).

The method 1400 may include radio frequency sputtering a second element in accordance with a second power frequency value different from the first power frequency value (in 1404).

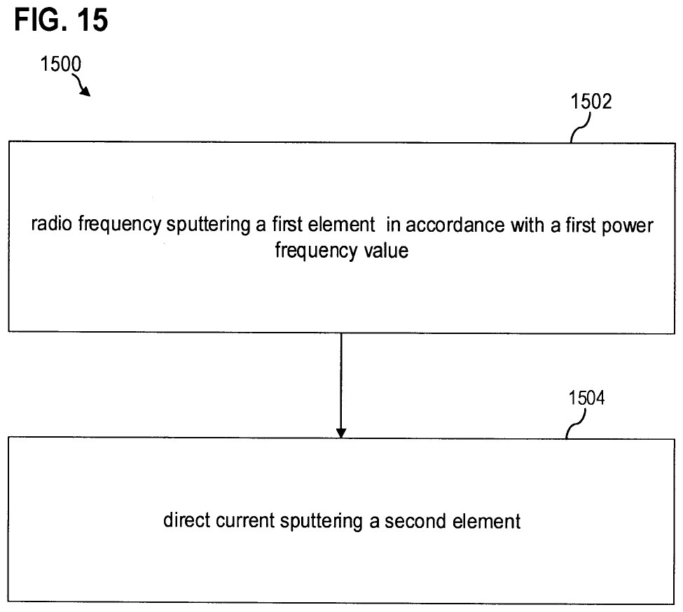

FIG. 15 shows a flow diagram of a method 1500 for controlling a sputtering process.

The method 1500 may include radio frequency sputtering a first element in accordance with a first power frequency value (in 1502).

The method 1500 may include direct current sputtering a second element (in 1504).

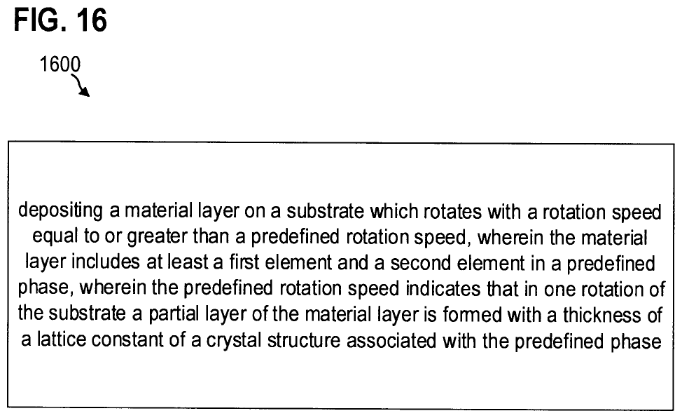

FIG. 16 shows a flow diagram of a method 1600 for controlling one or more operation parameters of a sputtering process.

The method 1600 may include depositing a material layer on a substrate which rotates with a rotation speed equal to or greater than a predefined rotation speed (in 1602). The material layer may include at least a first element and a second element in a predefined phase. The predefined rotation speed may indicate that in one rotation of the substrate a partial layer of the material layer is formed with a thickness of a lattice constant of a crystal structure associated with the predefined phase.

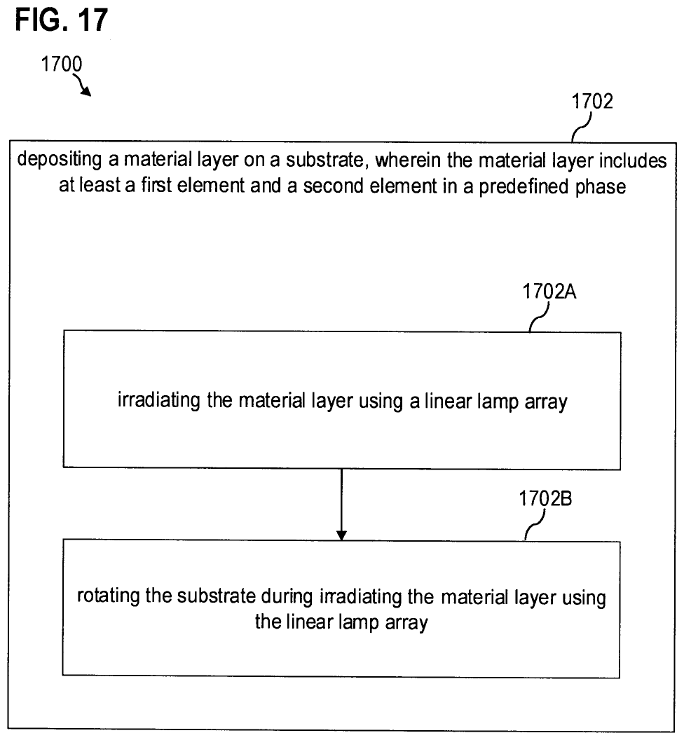

FIG. 17 shows a flow diagram of a method 1700 for controlling one or more operation parameters of a sputtering process.

The method 1700 may include depositing a material layer on a substrate (in 1702). The material layer may include at least a first element and a second element in a predefined phase.

The method 1700 may include, during and/or after depositing the material layer on the substrate (in 1702), irradiating the material layer using a linear lamp array (in 1702A).

The method 1700 may include, during irradiating the material layer using the linear lamp array (in 1702A), rotating the substrate (in 1702B).

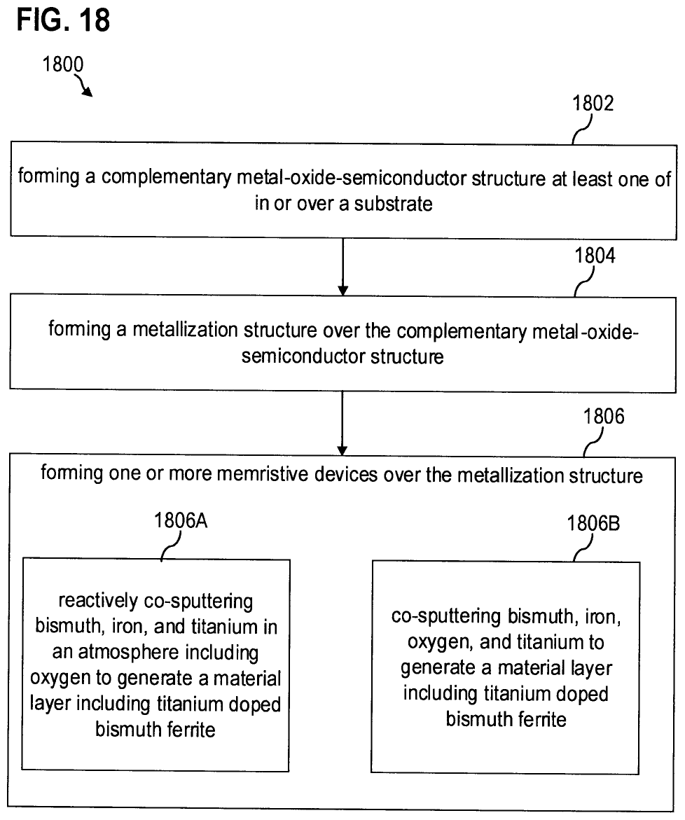

FIG. 18 shows a flow diagram of a method 1800 for forming one or more memristive devices.

The method 1800 may include forming a complementary metal-oxide-semiconductor structure at least one of in or over a substrate (in 1802).

The method 1800 may include forming a metallization structure over the complementary metal-oxide-semiconductor structure (in 1804).

The method 1800 may include forming one or more memristive devices over the metallization structure (in 1806). Forming the one or more memristive devices (in 1806) may either include reactively co-sputtering bismuth, iron, and titanium in an atmosphere including oxygen to generate a material layer including titanium doped bismuth ferrite (in 1806A) or co-sputtering bismuth, iron, oxygen, and titanium to generate a material layer including titanium doped bismuth ferrite (in 1806B).

Optionally, the method 1800 may include controlling one or more operation parameters of the sputtering in accordance with one or more control aspects described herein (e.g., using one or more of the herein described methods).

In the following, various examples are provided that may include one or more aspects described above with reference to sputtering at least the first element (e.g., Bi) and the second element (e.g., Fe) (and optionally the third element (e.g., Ti)), such as via on the devices (e.g., the sputter controller 108, the one or more sputter sources 104(n=1 to N)) and/or systems (e.g., the sputter system 100), and/or using one of the methods 700, 800, 900, 1000, 1100, 1200B, 1300, 1400, 1500, 1600, 1700, 1800. It may be intended that aspects described in relation one of the devices (e.g., the sputter controller 108, the one or more sputter sources 104(n=1 to N)) and/or the system 100 may apply also to one or more of the methods 700, 800, 900, 1000, 1100, 1200B, 1300, 1400, 1500, 1600, 1700, 1800, and vice versa.

Example 1 is a method including: depositing a material layer on a substrate, wherein the material layer includes at least a first element (e.g., Bi) and a second element (e.g., Fe) in a predefined atomic ratio, wherein the first element has a higher temperature-dependent re-evaporation rate from the substrate and/or the material layer than the second element; wherein depositing the material layer includes: generating a deposition material stream for deposition on the substrate, wherein the deposition material stream includes an atomic ratio of the first element to the second element higher than the predefined atomic ratio, and setting a temperature of the substrate to evaporate atoms of the first element from the substrate and/or the material layer such that the material layer has the predefined atomic ratio of the first element and the second element.

In Example 2, the subject matter of Example 1 can optionally include that the temperature of the substrate is set prior to generating the deposition material stream.

In Example 3, the subject matter of Example 1 or 2 can optionally include that the temperature of the substrate is set to a temperature value equal to or greater than a lower threshold value, wherein the lower threshold value represents a vapor pressure of the first element at a working pressure of an atmosphere the deposition material stream is generated in.

In Example 4, the subject matter of any one of Examples 1 to 3 can optionally include that the substrate includes a metal layer including a metal material and wherein the material layer is deposited on the metal layer; wherein the temperature of the substrate is set to a temperature value equal to or less than an upper threshold value, wherein the upper threshold value represents an upper limit of a diffusion-induced atomic concentration of the metal material within the material layer.

In Example 5, the subject matter of any one of Examples 1 to 4 can optionally include that generating the deposition material stream includes sputtering the first element from a first sputter target including the first element and sputtering the second element from a second sputter target including the second element, the second sputter target being different from the first sputter target.

In Example 6, the subject matter of Example 5 can optionally include that the first sputter target is mounted to a first sputter source and wherein the second sputter target is mounted to a second sputter source different from the first sputter source; or wherein the first sputter target and the second sputter target are mounted to a common sputter source.

In Example 7, the subject matter of any one of Examples 1 to 4 can optionally include that generating the deposition material stream includes sputtering the first element and the second element from a common sputter target including the first element and the second element.

In Example 8, the subject matter of any one of Examples 1 to 7 can optionally include that the material layer further includes oxygen; and wherein the deposition material stream is generated in an atmosphere including oxygen (e.g., by reactively co-sputtering the first element and the second element) (the atmosphere optionally further including an inert gas) or wherein the deposition material stream includes oxygen (e.g., in the case of two sputter targets: the first sputter target may include an oxide of the first element and/or the second sputter target may include an oxide of the second element; or in the case of a single sputter targets: the common sputter target may include an oxide of the first element and second element).

In Example 9, the subject matter of any one of Examples 1 to 8 can optionally include that, in a temperature range from about 400° C. to about 800° C., the temperature-dependent re-evaporation rate of the first element from the substrate and/or the material layer is at least two times the temperature-dependent re-evaporation rate of the second element from the substrate and/or the material layer.

In Example 10, the subject matter of any one of Examples 1 to 9 can optionally include that the material layer further includes a third element in a predefined atomic ratio to the first element and the second element, wherein the first element has a higher temperature-dependent re-evaporation rate from the substrate and/or the material layer than the third element.

In Example 11, the subject matter of Example 10 can optionally include that, in a temperature range from about 400° C. to about 800° C., the temperature-dependent re-evaporation rate of the first element from the substrate and/or the material layer is at least two times the temperature-dependent re-evaporation rate of the third element from the substrate and/or the material layer.

In Example 12, the subject matter of any one of Examples 1 to 11 can optionally include that the first element is bismuth and the second element is iron.

In Example 13, the subject matter of Example 12 can optionally include that the temperature of the substrate is set to have a temperature value in a range from about 600° C. to about 650° C. (e.g., a temperature value of about 630° C.).

In Example 14, the subject matter of Example 3 in combination with Example 12 or 13 can optionally include that the lower threshold value is, at a working pressure of about 0.2*10⁻² mbar, about 630° C.

In Example 14, the subject matter of Example 4 in combination with any one of Examples 12 to 14 can optionally include that the metal material is titanium and wherein upper threshold value is about 650° C.

In Example 16, the subject matter of any one of Examples 12 to 15 can optionally include that the predefined atomic ratio of the first element to the second element is about 1:1.

In Example 17, the subject matter of any one of Examples 12 to 16 can optionally include that the third element is titanium.

In Example 18, the subject matter of any one of Examples 1 to 17 can optionally include that the material layer includes a predefined phase which includes the first element and the second element; and wherein the method further includes: during depositing the material layer on the substrate, rotating the substrate with a rotation speed equal to or greater than a predefined rotation speed which indicates that in one rotation (revolution) of the substrate a partial layer of the material layer is formed with a thickness of (about) a lattice constant of a crystal structure associated with the predefined phase.

In Example 19, the subject matter of Example 18 in combination with any one of Examples 12 to 17 can optionally include that the predefined phase is bismuth ferrite (BiFeO₃).

In Example 20, the subject matter of Example 18 or 19 can optionally include that the deposition material stream is generated to impinge off-center on the substrate.

In Example 21, the subject matter of Example 20 can optionally include that the substrate is a wafer; and wherein the deposition material stream is generated to impinge on the wafer at about a middle radius of the wafer.

In Example 22, the subject matter of Example 20 or 21 can optionally include that generating the deposition material stream includes confocally co-sputtering the first element and the second element with the focus being off-center on the substrate.

In Example 23, the subject matter of Example 20 or 21 can optionally include that generating the deposition material stream includes generating a first deposition material stream by sputtering the first element and generating a second deposition material stream by sputtering the second element; and wherein the first deposition material stream is generated to impinge off-center on the substrate having a first focus and wherein the second deposition material stream is generated to impinge off-center on the substrate having a second focus different from the first focus.

Example 24 is a method including: determining a (e.g., priorly set or measured during deposition) temperature value representing a temperature of a substrate on which a material layer including at least a first element (e.g., Bi) and a second element (e.g., Fe) in a predefined atomic ratio is to be deposited; determining, based on the temperature value (and optionally a desired atomic ratio between the first element and the second element), a nominal power ratio between a first power associated with sputtering the first element and a second power associated with sputtering the second element; and setting a first power value of the first power and a second power value of the second power in accordance with the nominal power ratio.

In Example 25, the method of Example 24 can optionally further include: depositing the material layer on the substrate.

In Example 26, the subject matter of Example 25 can optionally include that depositing the material layer on the substrate includes sputtering the first element (e.g., from a first sputter target) in accordance with the first power value and sputtering the second element (e.g., from a second sputter target) in accordance with the second power value.

In Example 27, the method of Example 25 can optionally further include: during depositing the material layer on the substrate: detecting plasma properties associated with sputtering the first element and/or the second element, determining an adapted nominal power ratio between the first power and the second power based on the plasma properties, and controlling the first power and the second power in accordance with the adapted nominal power ratio.

In Example 28, the method of Example 25 can optionally further include: during depositing the material layer on the substrate: detecting plasma properties associated with sputtering the first element and/or the second element, controlling the temperature of the substrate based on the plasma properties.

In Example 29, the subject matter of any one of Examples 24 to 28 can optionally include that the temperature value is determined (e.g., measured) during depositing the material layer on the substrate.

In Example 30, the method of any one of Examples 24 to 29 can optionally further include: heating the substrate to a set temperature prior to depositing the material layer on the substrate.

In Example 31, the method of any one of Examples 24 to 30 can optionally further include: during depositing the material layer on the substrate, continuously (e.g., at predefined (e.g., regular) time intervals) detecting the temperature of the substrate and controlling the first power and the second power based on a respectively detected temperature value of the temperature of the substrate.

In Example 32, the subject matter of any one of Examples 24 to 31 can optionally include that depositing the material layer on the substrate includes generating a deposition material stream in an atmosphere including oxygen (e.g., by reactively co-sputtering the first element and the second element) (the atmosphere optionally further including an inert gas).

In Example 33, the method of Example 32 can optionally further include: during depositing the material layer on the substrate, detecting oxygen data representing an oxygen concentration in an environment of the substrate, and controlling, based on the oxygen data, an oxygen supply in accordance with a set oxygen concentration.

In Example 34, the method of Example 33 can optionally further include: detecting the oxygen data by: detecting an oxygen partial pressure (e.g., using mass spectrometry and/or a lambda probe); and/or provided that in combination with Example 25, determining one or more parameters representing electrical properties (e.g., a current, a voltage, a power, an impedance, etc.) of a first plasma associated with sputtering the first element and/or a second plasma associated with sputtering the second element, and determining an oxygen partial pressure based on the one or more parameters; and/or provided that in combination with Example 25, (e.g., optically) detecting a plasma emission of a first plasma associated with sputtering the first element and/or a second plasma associated with sputtering the second element, and determining, based on the plasma emission, an intensity of an oxygen characteristic.

In Example 35, the subject matter of any one of Examples 24 to 31, provided that in combination with Example 25, can optionally include that the first element is sputtered from a first sputter target which substantially consists of the first element and wherein the second element is sputtered from a second sputter target different from the first sputter target, wherein the second sputter target substantially consists of an oxide of the second element; or wherein the first element is sputtered from a first sputter target which substantially consists of an oxide of the first element and wherein the second element is sputtered from a second sputter target different from the first sputter target, wherein the second sputter target substantially consists of the second element; or wherein the first element is sputtered from a first sputter target which substantially consists of an oxide of the first element and wherein the second element is sputtered from a second sputter target different from the first sputter target, wherein the second sputter target substantially consists of an oxide of the second element.

In Example 36, the method of any one of Examples 24 to 35 can optionally further include: setting a temperature to which the substrate is to be heated.

In Example 37, the subject matter of Example 36 can optionally include that the temperature is set to a temperature value less than a threshold value which represents a vapor pressure of the first element at a working pressure of an atmosphere in which the material layer is to be deposited.

In Example 38, the subject matter of any one of Examples 24 to 37 can optionally include that the material layer further includes a third element.

In Example 39, the subject matter of Example 38 can optionally include that the third element is titanium.

In Example 40, the subject matter of any one of Examples 24 to 39 can optionally include that the first element is bismuth and the second element is iron.

In Example 41, the subject matter of Examples 24 and 40 can optionally include that the temperature to which the substrate is to be heated has a temperature value below 630° C. (e.g., below 600° C.).

In Example 42, the subject matter of Example 34 in combination with Example 40 or 41 can optionally include that the threshold value is, at a working pressure of about 0.2*10⁻² mbar, about 630° C.

In Example 43, the subject matter of Example 28 in combination with any one of Examples 40 to 42 can optionally include that controlling the power ratio includes: reducing the power ratio of the first power to the second power (e.g., by decreasing the first power and/or by increasing the second power) in the case that the temperature of the substrate increases; and/or increasing the power ratio of the first power to the second power (e.g., by increasing the first power and/or by decreasing the second power) in the case that the temperature of the substrate decreases.

In Example 44, the subject matter of any one of Examples 24 to 43 can optionally include that the material layer includes a predefined phase which includes the first element and the second element; and wherein the method further includes: during depositing the material layer on the substrate, rotating the substrate with a rotation speed equal to or greater than a predefined rotation speed which indicates that in one rotation (revolution) of the substrate a partial layer of the material layer is formed with a thickness of (about) a lattice constant of a crystal structure associated with the predefined phase.

In Example 45, the subject matter of Example 44 in combination with any one of Examples 40 to 43 can optionally include that the predefined phase is bismuth ferrite (BiFeO₃).

In Example 46, the subject matter of Example 44 or 45 can optionally include that depositing the material layer includes generating a deposition material stream which impinges off-center on the substrate.

In Example 47, the subject matter of Example 46 can optionally include that the substrate is a wafer; and wherein the deposition material stream is generated to impinge on the wafer at about a middle radius of the wafer.

In Example 48, the subject matter of Example 46 or 47 can optionally include that generating the deposition material stream includes confocally co-sputtering the first element and the second element with the focus being off-center on the substrate.

In Example 49, the subject matter of Example 46 or 47 can optionally include that generating the deposition material stream includes generating a first deposition material stream by sputtering the first element and generating a second deposition material stream by sputtering the second element; and wherein the first deposition material stream is generated to impinge off-center on the substrate having a first focus and wherein the second deposition material stream is generated to impinge off-center on the substrate having a second focus different from the first focus.

Example 50 is a sputter controller including: a power supply configured to: apply a first voltage in accordance with a first power to a first sputter source (e.g., to sputter a first element from a first target in direction of a substrate), and apply a second voltage in accordance with a second power to a second sputter source (e.g., to sputter a second element from a second target in direction of the substrate, the second element being different from the first element); and a control device configured to: receive temperature data representing a temperature of a substrate; determine a power ratio between the first power and the second power based on the temperature of the substrate, and control the power supply to apply the first voltage and the second voltage in accordance with the power ratio between the first power and the second power.

In Example 51, the subject matter of Example 50 can optionally include that the temperature data includes the temperature of the substrate; and/or wherein the temperature data includes the temperature of a heater (e.g., a resistive heater and/or a lamp array) configured to heat the substrate to set temperature.

Example 52 is a sputter system including: the sputter controller according to Example 50 or 51; and a temperature sensor configured to detect a temperature representing the temperature of the substrate.

In Example 53, the subject matter of Example 52 can optionally include that the temperature sensor is configured to detect the temperature of the substrate; and/or wherein the sputter system further includes a heater configured to heat the substrate to a set temperature and wherein the temperature sensor is configured to detect a temperature representing a temperature of the substrate.

In Example 54, the sputter system of Example 52 or 53 can optionally further include: a substrate holder on which a substrate can be placed; and a motor configured to drive the substrate holder to rotate in accordance with a set rotation speed; wherein the control device of the sputter controller is configured to set the rotation speed based on the first power and the second power.

In Example 55, the sputter system of any one of Examples 52 to 54 can optionally further include: a vacuum chamber; and a device (e.g., a mass flow controller and/or a gate) configured to define an oxygen flow into the vacuum chamber; wherein the control device of the sputter controller is configured to control the device to define the oxygen flow depending on the power ratio between the first power and the second power.

Example 56 is a method including: sputtering at least a first element (e.g., Bi) in accordance with a first power and a second element (e.g., Fe) in accordance with a second power to deposit, on a substrate, a material layer including the first element and the second element; during sputtering the first element and the second element: (e.g., continuously) detecting plasma properties associated with sputtering the first element and/or the second element, and controlling, based on the plasma properties, a sputter rate ratio between a first sputter rate associated with sputtering the first element and a second sputter rate associated with sputtering the second element.

In Example 57, the subject matter of Example 56 can optionally include that sputtering the first element and the second element includes: sputtering the first element from a first sputter source and sputtering the second element from a second sputter source different from the first sputter source, wherein the plasma properties include plasma properties of a first plasma associated with sputtering the first element from the first sputter source and/or plasma properties of a second plasma associated with sputtering the second element from the second sputter source; or sputtering the first element and the second element from a common target, wherein the plasma properties are plasma properties of a plasma associated with sputtering from the common target.

In Example 58, the method of Example 56 or 57 can optionally further include: wherein detecting plasma properties associated with sputtering the first element and/or the second element includes: optically detecting plasma properties associated with sputtering the first element and/or the second element (e.g., using optical emission spectroscopy (OES) (e.g., via OES imaging), interferometry, atomic absorption spectroscopy, and/or laser-induced fluorescence, etc.).

In Example 59, the method of any one of Examples 56 to 58 can optionally further include: wherein controlling the sputter rate ratio includes controlling a power ratio between the first power and the second power; and/or wherein controlling the sputter rate ratio includes controlling a first magnetic field associated with sputtering the first element and/or controlling a second magnetic field associated with sputtering the second element; and/or wherein sputtering the first element includes radio frequency (RF) sputtering the first element and wherein controlling the sputter rate ratio includes controlling a power frequency associated with radio frequency (RF) sputtering the first element; and/or wherein sputtering the second element includes radio frequency (RF) sputtering the second element and wherein controlling the sputter rate ratio includes controlling a power frequency associated with radio frequency (RF) sputtering the second element; and/or wherein controlling the sputter rate ratio includes controlling a pressure of an atmosphere in which the first element and the second element are sputtered.

In Example 60, the method of any one of Examples 56 to 59 can optionally further include: heating the substrate to a set temperature prior to sputtering the first element and the second element.

In Example 61, the subject matter of Example 60 can optionally include that the temperature is set to a temperature value less than a threshold value which represents a vapor pressure of the first element at a working pressure of an atmosphere in which the material layer is to be deposited.

In Example 62, the method of any one of Examples 56 to 61 can optionally further include: during sputtering the first element and the second element, continuously (e.g., at predefined (e.g., regular) time intervals) detecting a temperature of the substrate; wherein the sputter rate ratio between the first sputter rate and the second sputter rate is controlled based on the plasma properties and based on a respectively detected temperature value of the temperature of the substrate.

In Example 63, the subject matter of any one of Examples 56 to 62 can optionally include that sputtering the first element and the second element includes sputtering the first element and the second element in an atmosphere including oxygen (e.g., by reactive sputtering the first element and the second element) (the atmosphere optionally further including an inert gas).

In Example 64, the method of Example 63 can optionally further include: during sputtering the first element and the second element, controlling an oxygen flow depending on the sputter rate ratio between the first sputter rate and the second sputter rate.

In Example 65, the subject matter of any one of Examples 56 to 64 can optionally include that the first element is bismuth and the second element is iron.

In Example 66, the subject matter of any one of Examples 60 to 65 can optionally include that the set temperature has a temperature value below 630° C.

In Example 67, the subject matter of Example 61 in combination with Example 65 or 66 can optionally include that the threshold value is, at a working pressure of about 0.2*10⁻² mbar, about 630° C.

In Example 68, the subject matter of any one of Examples 56 to 67 can optionally include that the material layer includes a predefined phase which includes the first element and the second element; and wherein the method further includes: during sputtering the first element and the second element, rotating the substrate with a rotation speed equal to or greater than a predefined rotation speed which indicates that in one rotation (revolution) of the substrate a partial layer of the material layer is formed with a thickness of (about) a lattice constant of a crystal structure associated with the predefined phase.

In Example 69, the subject matter of Example 68 in combination with any one of Examples 65 to 67 can optionally include that the predefined phase is bismuth ferrite (BiFeO₃).

In Example 70, the subject matter of Example 68 or 69 can optionally include that sputtering the first element and the second element includes sputtering the first element and the second element to impinge off-center on the substrate.

In Example 71, the subject matter of Example 70 can optionally include that the substrate is a wafer; and wherein the first element and the second element are sputtered to impinge on the wafer at about a middle radius of the wafer.

In Example 72, the subject matter of Example 70 or 71 can optionally include that sputtering the first element and the second element includes confocally co-sputtering the first element and the second element with the focus being off-center on the substrate.

In Example 73, the subject matter of Example 70 or 71 can optionally include that sputtering the first element and the second element includes sputtering the first element to impinge off-center on the substrate having a first focus and sputtering the second element to impinge off-center on the substrate having a second focus different from the first focus.

Example 74 is a sputter controller including: a power supply configured to: operate a first sputter source configured to sputter bismuth, and operate a second sputter source configured to sputter iron; and a control device configured to: receive plasma data representing plasma properties associated with sputtering bismuth and/or iron, determine, based on the plasma properties, a sputter rate ratio between a bismuth sputter rate associated with sputtering bismuth and an iron sputter rate associated with sputtering iron, and control the operation of the first sputter source and/or the second sputter source in accordance with the sputter rate ratio between the bismuth sputter rate and the iron sputter rate.

In Example 75, the subject matter of Example 74 can optionally include that the power supply is configured to operate the first sputter source to radio frequency (RF) sputter bismuth in accordance with a first power frequency; and wherein the control device is configured to control the operation of the first sputter source in accordance with the sputter rate ratio between the bismuth sputter rate and the iron sputter rate by controlling the first power frequency.

In Example 76, the subject matter of Example 74 or 75 can optionally include that the power supply is configured to operate the second sputter source to radio frequency (RF) sputter iron in accordance with a second power frequency; and wherein the control device is configured to control the operation of the second sputter source in accordance with the sputter rate ratio between the bismuth sputter rate and the iron sputter rate by controlling the second power frequency.

In Example 77, the subject matter of any one of Examples 74 to 76 can optionally include that the power supply is configured to operate the first sputter source to radio frequency (RF) sputter bismuth in accordance with a first power frequency and to operate the second sputter source to radio frequency (RF) sputter iron in accordance with a second power frequency; and wherein the control device is configured to: determine, based on the sputter rate ratio between the bismuth sputter rate and the iron sputter rate, a frequency ratio between the first power frequency and the second power frequency, and control the operation of the first sputter source and/or the second sputter source in accordance with the sputter rate ratio between the bismuth sputter rate and the iron sputter rate by controlling the operation of the first sputter source and/or the second sputter source in accordance with the frequency ratio.

Example 78 is a sputter system including: the sputter controller according to any one of Examples 74 to 77; the first sputter source; and the second sputter source.

In Example 79, the sputter system of Example 78 can optionally further include: an optical sensor configured to detect the plasma properties.

In Example 80, the subject matter of Example 78 or 79 can optionally include that the first sputter source is a first magnetron sputter source including a bismuth target, one or more first magnets for generating a first magnetic field through the bismuth target, and a first motor configured to change a distance between the bismuth target and the one or more first magnets; wherein the control device is configured to control the operation of the first sputter source in accordance with the sputter rate ratio between the bismuth sputter rate and the iron sputter rate by controlling the first motor to change the distance between the bismuth target and the one or more first magnets.

In Example 81, the subject matter of any one of Examples 78 to 80 can optionally include that the second sputter source is second magnetron sputter source including an iron target, one or more second magnets for generating a second magnetic field through the iron target, and a second motor configured to change a distance between the iron target and the one or more second magnets; wherein the control device is configured to control the operation of the second sputter source in accordance with the sputter rate ratio between the bismuth sputter rate and the iron sputter rate by controlling the second motor to change the distance between the iron target and the one or more second magnets.

In Example 82, the subject matter of Example 78 or 79 can optionally include that the first sputter source is a first magnetron sputter source including a bismuth target, one or more first magnets for generating a first magnetic field through the bismuth target, and a first motor configured to change a first distance between the bismuth target and the one or more first magnets; wherein the second sputter source is second magnetron sputter source including an iron target, one or more second magnets for generating a second magnetic field through the iron target, and a second motor configured to change a second distance between the iron target and the one or more second magnets; and wherein the control device is configured to: determine, based on the sputter rate ratio between the bismuth sputter rate and the iron sputter rate, a distance ratio between the first distance and the second distance, and control the operation of the first sputter source and/or the second sputter source in accordance with the sputter rate ratio between the bismuth sputter rate and the iron sputter rate by controlling the operation of the first sputter source and/or the second sputter source in accordance with the distance ratio.

In Example 83, the sputter system of any one of Examples 78 to 82 can optionally further include: a vacuum chamber; and a device (e.g., a mass flow controller and/or a gate) configured to control an atmospheric pressure in the vacuum chamber; wherein the control device is configured to: determine, based on the sputter rate ratio, a pressure value of the atmospheric pressure, and control the operation of the first sputter source in accordance with the sputter rate ratio between the bismuth sputter rate and the iron sputter rate by controlling the device to control the atmospheric pressure in accordance with the pressure value.

In Example 84, the sputter system of any one of Examples 78 to 83 can optionally further include: a substrate holder on which a substrate can be placed; and a motor configured to drive the substrate holder to rotate in accordance with a set rotation speed; wherein the control device of the sputter controller is configured to set the rotation speed based on the first power and the second power.

In Example 85, the sputter system of any one of Examples 78 to 84 can optionally further include: a vacuum chamber; and a device (e.g., a mass flow controller and/or a gate) configured to define an oxygen flow into the vacuum chamber; wherein the control device of the sputter controller is configured to control the device to define the oxygen flow depending on the sputter ratio.

Example 86 is a dual loop control method including: sputtering at least a first element (e.g., Bi) in accordance with a first power and a second element (e.g., Fe) in accordance with a second power to deposit, on a substrate, a material layer including the first element and the second element; and during sputtering the first element and the second element, controlling the first power and the second power via a first control loop and a second control loop; wherein the first control loop includes: (e.g., continuously (e.g., at predefined (e.g., regular) time intervals)) detecting a temperature of the substrate, and controlling the first power and the second power to adapt a power ratio between the first power and the second power based on the temperature of the substrate; wherein the second control loop includes: (e.g., continuously (e.g., at predefined (e.g., regular) time intervals)) detecting plasma properties associated with sputtering the first element and/or the second element, and controlling the first power and the second power to adapt the power ratio between the first power and the second power based on the plasma properties.

In Example 87, the dual loop control method of Example 86 can optionally further include: heating the substrate to a set temperature prior to sputtering the first element and the second element.

In Example 88, the subject matter of Example 87 can optionally include that the set temperature has a temperature value less than a threshold value which represents a vapor pressure of the first element at a working pressure of an atmosphere in which the first element and the second element are sputtered.

In Example 89, the subject matter of any one of Examples 86 to 88 can optionally include that sputtering the first element and the second element includes sputtering the first element and the second element in an atmosphere including oxygen (e.g., by reactively co-sputtering the first element and the second element) (the atmosphere optionally further including an inert gas).

In Example 90, the dual loop method of Example 89 can optionally further include: during sputtering the first element and the second element, controlling an oxygen flow depending on the power ratio between the first power and the second power

In Example 91, the subject matter of any one of Examples 86 to 90 can optionally include that sputtering the first element and the second element includes: co-sputtering the first element from a first sputter target which substantially consists of the first element and the second element from a second sputter target different from the first sputter target, wherein the second sputter target substantially consists of an oxide of the second element; or co-sputtering the first element from a first sputter target which substantially consists of an oxide of the first element and the second element from a second sputter target different from the first sputter target, wherein the second sputter target substantially consists of the second element; or co-sputtering the first element from a first sputter target which substantially consists of an oxide of the first element and the second element from a second sputter target different from the first sputter target, wherein the second sputter target substantially consists of an oxide of the second element.

In Example 92, the subject matter of any one of Examples 86 to 91 can optionally include that sputtering the first element and the second element includes: sputtering the first element from a first sputter source and sputtering the second element from a second sputter source different from the first sputter source; or sputtering the first element and the second element from a common target.

In Example 93, the subject matter of any one of Examples 86 to 92 can optionally include that the first control loop further includes: determining, whether the temperature of the substrate changes, and in the case that it is determined that the temperature of the substrate changes, controlling the first power and the second power to adapt the power ratio between the first power and the second power based on a change of the temperature of the substrate.

In Example 94, the subject matter of any one of Examples 86 to 93 can optionally include that the temperature of the substrate and the plasma properties are continuously detected during sputtering the first element and the second element.

In Example 95, the subject matter of Example 94 can optionally include that the temperature of the substrate is continuously detected according to a first (e.g., regular) cycle and wherein the plasma properties are continuously detected according to a second (e.g., regular) cycle, wherein a length of the first cycle is greater than a length of the second cycle.

In Example 96, the subject matter of any one of Examples 86 to 95 can optionally include that a cycle of the second control loop is shorter than a cycle of the first control loop.

In Example 97, the subject matter of any one of Examples 86 to 96 can optionally include that detecting plasma properties associated with sputtering the first element and/or the second element includes: optically detecting plasma properties associated with sputtering the first element and/or the second element (e.g., using optical emission spectroscopy (OES) (e.g., via OES imaging), interferometry, atomic absorption spectroscopy, and/or laser-induced fluorescence, etc.).

In Example 98, the subject matter of any one of Examples 86 to 97 can optionally include that the first element is bismuth and the second element is iron.

In Example 99, the subject matter of Examples 93 and 98 can optionally include that controlling the power ratio within the first control loop includes: reducing the power ratio of the first power to the second power (e.g., by decreasing the first power and/or by increasing the second power) in the case that the temperature of the substrate increases; and/or increasing the power ratio of the first power to the second power (e.g., by increasing the first power and/or by decreasing the second power) in the case that the temperature of the substrate decreases.

In Example 100, the subject matter of Example 87 in combination with Example 98 or 99 can optionally include that the set temperature has a temperature value below 630° C. (e.g., below 600° C.).

In Example 101, the subject matter of Example 88 in combination with any one of Examples 98 to 100 can optionally include that the threshold value is, at a working pressure of about 0.2*10⁻² mbar, about 630° C.

In Example 102, the subject matter of any one of Examples 98 to 101 can optionally include that the material layer includes a predefined phase which includes the first element and the second element; and wherein the method further includes: during sputtering the first element and the second element, rotating the substrate with a rotation speed equal to or greater than a predefined rotation speed which indicates that in one rotation (revolution) of the substrate a partial layer of the material layer is formed with a thickness of (about) a lattice constant of a crystal structure associated with the predefined phase.

In Example 103, the subject matter of Example 102 in combination with any one of Example 98 to 101 can optionally include that the predefined phase is bismuth ferrite (BiFeO₃).

In Example 104, the subject matter of Example 102 or 103 can optionally include that sputtering the first element and the second element includes sputtering the first element and the second element to impinge off-center on the substrate.

In Example 105, the subject matter of Example 104 can optionally include that the substrate is a wafer; and wherein the first element and the second element are sputtered to impinge on the wafer at about a middle radius of the wafer.

In Example 106, the subject matter of Example 104 or 105 can optionally include that sputtering the first element and the second element includes confocally co-sputtering the first element and the second element with the focus being off-center on the substrate.

In Example 107, the subject matter of Example 104 or 105 can optionally include that sputtering the first element and the second element includes sputtering the first element to impinge off-center on the substrate having a first focus and sputtering the second element to impinge off-center on the substrate having a second focus different from the first focus.

Example 108 is a sputter controller including: a power supply configured to: apply a first voltage in accordance with a first power to a first sputter source (e.g., to sputter a first element from a first target in direction of a substrate), and apply a second voltage in accordance with a second power to a second sputter source (e.g., to sputter a second element from a second target in direction of the substrate, the second element being different from the first element); and a control device configured to: (e.g., continuously (e.g., at predefined (e.g., regular) time intervals)) receive plasma data representing plasma properties associated with sputtering the first element and/or the second element; determine a power ratio between the first power and the second power based on the plasma data; control the power supply to apply the first voltage and the second voltage in accordance with the power ratio between the first power and the second power; (e.g., continuously (e.g., at predefined (e.g., regular) time intervals)) receive temperature data representing a temperature of the material layer; determine, whether the temperature of the substrate changes; in the case that it is determined that the temperature of the substrate changes, controlling the first power and the second power to adapt the power ratio between the first power and the second power based on a change of the temperature of the substrate.

In Example 109, the subject matter of Example 108 can optionally include that the temperature data includes the temperature of the substrate; and/or wherein the temperature data includes the temperature of a heater (e.g., a resistive heater and/or a lamp array) configured to heat the substrate to set temperature.

Example 110 is a sputter system including: the sputter controller according to Example 108 or 109; and a temperature sensor configured to detect a temperature representing the temperature of the substrate and to provide temperature data in accordance with the detected temperature to the sputter controller.

In Example 111, the subject matter of Example 110 can optionally include that the temperature sensor is configured to detect the temperature of the substrate; and/or wherein the sputter system further includes a heater configured to heat the substrate to a set temperature and wherein the temperature sensor is configured to detect a temperature representing a temperature of the substrate.

In Example 112, the sputter system of Example 110 or 111 can optionally further include: a substrate holder on which a substrate can be placed; and a motor configured to drive the substrate holder to rotate in accordance with a set rotation speed; wherein the control device of the sputter controller is configured to set the rotation speed based on the power ratio between the first power and the second power.

In Example 113, the sputter system of any one of Examples 110 to 112 can optionally further include: a vacuum chamber; and a device (e.g., a mass flow controller and/or a gate) configured to define an oxygen flow into the vacuum chamber; wherein the control device of the sputter controller is configured to control the device to define the oxygen flow depending on the power ratio between the first power and the second power.

In Example 114, the sputter system of any one of Examples 110 to 113 can optionally further include: an optical sensor configured to detect the plasma properties.

Example 115 is a method including: sputtering at least a first element (e.g., Bi) and a second element (e.g., Fe) to deposit, on a substrate, a material layer including the first element and the second element; during sputtering the first element and the second element: (e.g., continuously) detecting a temperature value representing a temperature of the substrate; determining, based on the temperature value, one or more operation parameters of the sputtering; and controlling the sputtering based on the one or more operation parameters.

In Example 116, the method of Example 115 can optionally further include: heating the substrate to a set temperature prior to sputtering the first element and the second element.

In Example 117, the subject matter of Example 115 or 116 can optionally include that a temperature value of the set temperature is less than a threshold value which represents a vapor pressure of the first element at a working pressure of an atmosphere in which the material layer is deposited.

Example 118 is a method including: sputtering at least a first element (e.g., Bi) and a second element (e.g., Fe) to deposit, on a substrate, a material layer including the first element and the second element; during sputtering the first element and the second element: (e.g., continuously) detecting plasma properties associated with sputtering the first element and/or the second element; determining, based on the plasma properties, one or more operation parameters of the sputtering; and controlling the sputtering based on the one or more operation parameters.

In Example 119, the subject matter of Example 118 can optionally include that the one or more operation parameters include a temperature value; and wherein controlling the sputtering includes heating or cooling the substrate to the temperature value.

In Example 120, the subject matter of Example 118 or 119 can optionally include that detecting plasma properties associated with sputtering the first element and/or the second element includes: optically detecting plasma properties associated with sputtering the first element and/or the second element (e.g., using optical emission spectroscopy (OES) (e.g., via OES imaging), interferometry, atomic absorption spectroscopy, and/or laser-induced fluorescence, etc.).

In Example 121, the subject matter of any one of Examples 118 to 120 can optionally include that sputtering the first element and the second element includes: sputtering the first element from a first sputter source and sputtering the second element from a second sputter source different from the first sputter source, wherein the plasma properties include plasma properties of a first plasma associated with sputtering the first element from the first sputter source and/or plasma properties of a second plasma associated with sputtering the second element from the second sputter source; or sputtering the first element and the second element from a common target, wherein the plasma properties are plasma properties of a plasma associated with sputtering from the common target.

In Example 122, the subject matter of any one of Examples 118 to 121 can optionally include that sputtering the first element and the second element includes sputtering the first element and the second element in an atmosphere including oxygen (e.g., by reactively co-sputtering the first element and the second element) (the atmosphere optionally further including an inert gas).

In Example 123, the method of Example 122 can optionally further include: wherein the one or more operation parameters include an oxygen partial pressure; and wherein controlling the sputtering includes controlling an oxygen supply based on the oxygen partial pressure.

In Example 124, the subject matter of Example 123 can optionally include that determining the oxygen partial pressure based on the plasma properties includes determining one or more parameters representing electrical properties (e.g., a current, a voltage, a power, an impedance, etc.) of a first plasma associated with sputtering the first element and/or a second plasma associated with sputtering the second element, and determining the oxygen partial pressure based on the one or more parameters; and/or wherein detecting plasma properties includes detecting a plasma emission of a first plasma associated with sputtering the first element and/or a second plasma associated with sputtering the second element, determining, based on the plasma emission, an intensity of an oxygen characteristic, wherein determining the oxygen partial pressure includes determining the oxygen partial pressure using the oxygen characteristic.

In Example 125, the method of any one of Examples 118 to 124 can optionally further include: during sputtering the first element and the second element, continuously (e.g., at predefined (e.g., regular) time intervals) detecting a temperature of the substrate; and wherein the one or more operation parameters include the temperature of the substrate.

In Example 126, the subject matter of any one of Examples 115 to 125 can optionally include that sputtering the first element and the second element includes sputtering the first element in accordance with a first power and the second element in accordance with a second power; and wherein the one or more operation parameters include a power ratio between the first power and the second power, and wherein controlling the sputtering includes controlling the first power and the second power in accordance with the power ratio.

In Example 127, the subject matter of any one of Examples 115 to 126 can optionally include that sputtering the first element includes radio frequency (RF) sputtering the first element in accordance with a first power and a first power frequency; wherein sputtering the second element includes direct-current (DC) sputtering the second element in accordance with a second power; and wherein the one or more operation parameters include a power ratio between the first power and the second power and wherein controlling the sputtering includes controlling the first power and the second power in accordance with the power ratio, and/or wherein the one or more operation parameters include a frequency value of the first power frequency and wherein controlling the sputtering includes controlling the sputtering of the first element in accordance with the frequency value.

In Example 128, the subject matter of any one of Examples 115 to 126 can optionally include that sputtering the second element includes radio frequency (RF) sputtering the second element in accordance with a second power and a second power frequency; wherein sputtering the first element includes direct-current (DC) sputtering the first element in accordance with a first power; and wherein the one or more operation parameters include a power ratio between the first power and the second power and wherein controlling the sputtering includes controlling the first power and the second power in accordance with the power ratio, and/or wherein the one or more operation parameters include a frequency value of the second power frequency and wherein controlling the sputtering includes controlling the sputtering of the second element in accordance with the frequency value.

In Example 129, the subject matter of any one of Examples 115 to 126 can optionally include that sputtering the first element includes radio frequency (RF) sputtering the first element in accordance with a first power and a first power frequency; wherein sputtering the second element includes radio frequency (RF) sputtering the second element in accordance with a second power and a second power frequency; and wherein the one or more operation parameters include a power ratio between the first power and the second power and wherein controlling the sputtering includes controlling the first power and the second power in accordance with the power ratio, and/or wherein the one or more operation parameters include a frequency ratio between the first power frequency and the second power frequency and wherein controlling the sputtering includes controlling the sputtering of the first element and the second element in accordance with the frequency ratio.

In Example 130, the subject matter of any one of Examples 115 to 129 can optionally include that sputtering the first element and the second element includes sputtering the first element and the second element in an atmosphere including oxygen (e.g., by reactively co-sputtering the first element and the second element) (the atmosphere optionally further including an inert gas).

In Example 131, the subject matter of Example 130 can optionally include that the first element is sputtered from a first sputter target which substantially consists of the first element and wherein the second element is sputtered from a second sputter target different from the first sputter target, wherein the second sputter target substantially consists of an oxide of the second element; or wherein the first element is sputtered from a first sputter target which substantially consists of an oxide of the first element and wherein the second element is sputtered from a second sputter target different from the first sputter target, wherein the second sputter target substantially consists of the second element; or wherein the first element is sputtered from a first sputter target which substantially consists of an oxide of the first element and wherein the second element is sputtered from a second sputter target different from the first sputter target, wherein the second sputter target substantially consists of an oxide of the second element.

In Example 130, the subject matter of any one of Examples 115 to 129 can optionally include that sputtering the first element includes magnetron sputtering the first element from a first target and wherein sputtering the second element includes magnetron sputtering the second element from a second target; and wherein the one or more operation parameters include a distance ratio between a first distance and a second distance, wherein the first distance is a distance between the first target and one or more first magnets associated with magnetron sputtering the first element and wherein the second distance is a distance between the second target and one or more second magnets associated with magnetron sputtering the second element.

In Example 131, the subject matter of any one of Examples 115 to 130 can optionally include that sputtering the first element and the second element includes sputtering the first element and the second element in an atmosphere; and wherein the one or more operation parameters include a pressure value representing a pressure of the atmosphere, and wherein controlling the sputtering includes controlling the pressure of the atmosphere in accordance with the pressure value.

In Example 132, the subject matter of any one of Examples 115 to 131 can optionally include that the material layer further includes a third element.

In Example 133, the subject matter of Example 132 can optionally include that the third element is titanium.

In Example 134, the subject matter of any one of Examples 115 to 133 can optionally include that the first element is bismuth and the second element is iron.

In Example 135, the method of any one of Examples 116 to 134 can optionally further include that the temperature to which the substrate is to be heated has a temperature value below 630° C. (e.g., below 600° C.).

In Example 136, the subject matter of Example 117 in combination with Example 134 or 135 can optionally include that the threshold value is, at a working pressure of about 0.2*10⁻² mbar, about 630° C.

In Example 137, the subject matter of any one of Examples 115 to 136 can optionally include that the material layer includes a predefined phase which includes the first element and the second element; and wherein the method further includes: during sputtering the first element and the second element, rotating the substrate with a rotation speed equal to or greater than a predefined rotation speed which indicates that in one rotation (revolution) of the substrate a partial layer of the material layer is formed with a thickness of (about) a lattice constant of a crystal structure associated with the predefined phase.

In Example 138, the subject matter of Example 137 in combination with any one of Examples 134 to 136 can optionally include that the predefined phase is bismuth ferrite (BiFeO₃).

In Example 139, the subject matter of Example 137 or 138 can optionally include that sputtering the first element and the second element includes generating a deposition material stream which impinges off-center on the substrate.

In Example 140, the subject matter of Example 139 can optionally include that the substrate is a wafer; and wherein the deposition material stream is generated to impinge on the wafer at about a middle radius of the wafer.

In Example 141, the subject matter of Example 139 or 140 can optionally include that generating the deposition material stream includes confocally co-sputtering the first element and the second element with the focus being off-center on the substrate.

In Example 142, the subject matter of Example 139 or 140 can optionally include that generating the deposition material stream includes generating a first deposition material stream by sputtering the first element and generating a second deposition material stream by sputtering the second element; and wherein the first deposition material stream is generated to impinge off-center on the substrate having a first focus and wherein the second deposition material stream is generated to impinge off-center on the substrate having a second focus different from the first focus.

Example 143 is a sputter controller including: a power supply configured to operate one or more sputter sources, wherein the one or more sputter sources are configured to sputter at least a first element and a second element; and a control device configured to: receive temperature data representing a temperature of a substrate, determine, based on the temperature of the substrate, one or more operation parameters of the one or more sputter sources; and control the operation of the one or more sputter sources based on the one or more operation parameters.

In Example 144, the subject matter of Example 143 can optionally include that the temperature data includes the temperature of the substrate; and/or wherein the temperature data includes the temperature of a heater (e.g., a resistive heater and/or a lamp array) configured to heat the substrate to set temperature.

Example 145 is a sputter controller including: a power supply configured to operate one or more sputter sources, wherein the one or more sputter sources are configured to sputter at least a first element and a second element; and a control device configured to: receive plasma data representing plasma properties associated with sputtering the first element and/or the second element, determine, based on the plasma properties, one or more operation parameters of the one or more sputter sources; and control the operation of the one or more sputter sources based on the one or more operation parameters.

In Example 146, the subject matter of any one of Examples 143 to 145 can optionally include that the power supply is configured to operate the one or more sputter sources to radio frequency (RF) sputter the first element in accordance with a first power frequency; and wherein the one or more operation parameters include a frequency value of the first power frequency and wherein the control device is configured to control the operation of the one or more sputter sources to radio frequency (RF) sputter the first element in accordance with the frequency value of the first power frequency.

In Example 147, the subject matter of any one of Examples 143 to 145 can optionally include that the power supply is configured to operate the one or more sputter sources to radio frequency (RF) sputter the second element in accordance with a second power frequency; and wherein the one or more operation parameters include a frequency value of the second power frequency and wherein the control device is configured to control the operation of the one or more sputter sources to radio frequency (RF) sputter the second element in accordance with the frequency value of the second power frequency.

In Example 148, the subject matter of any one of Examples 143 to 145 can optionally include that the power supply is configured to operate the one or more sputter sources to radio frequency (RF) sputter the first element in accordance with a first power frequency and to radio frequency (RF) sputter the second element in accordance with a second power frequency; wherein the one or more operation parameters include a frequency ratio between the first power frequency and the second power frequency; and wherein the control device is configured to control the operation of the one or more sputter sources by controlling the first power frequency and the second power frequency in accordance with the frequency ratio.

Example 149 is a sputter system including: the sputter controller according to any one of Examples 143 to 148; and the one or more sputter sources.

In Example 150, the sputter system of Example 149 can optionally further include: a temperature sensor configured to detect a temperature representing the temperature of the substrate.

In Example 151, the subject matter of Example 150 can optionally include that the temperature sensor is configured to detect the temperature of the substrate; and/or wherein the sputter system further includes a heater configured to heat the substrate to a set temperature and wherein the temperature sensor is configured to detect a temperature representing a temperature of the substrate.

In Example 152, the subject matter of any one of Examples 149 to 151, provided that in combination with Example 145 can optionally include that the sputter system further includes: an optical sensor configured to detect the plasma properties.

In Example 153, the subject matter of any one of Examples 149 to 152 can optionally include that the one or more sputter sources are configured to sputter the first element from a first target and wherein the one or more sputter sources include one or more first magnets for generating a first magnetic field through the first target and a first motor configured to change a first distance between the first target and the one or more first magnets; and wherein the one or more operation parameters include a distance value of the first distance and wherein the control device is configured to control the operation of the one or more sputter sources by controlling the first motor to change the first distance in accordance with the distance value.

In Example 154, the subject matter of any one of Examples 149 to 153 can optionally include that the one or more sputter sources are configured to sputter the second element from a second target and wherein the one or more sputter sources include one or more second magnets for generating a second magnetic field through the second target, and a second motor configured to change a second distance between the second target and the one or more second magnets; and wherein the one or more operation parameters include a distance value of the second distance and wherein the control device is configured to control the operation of the one or more sputter sources by controlling the second motor to change the second distance in accordance with the distance value.

In Example 155, the subject matter of any one of Examples 149 to 152 can optionally include that the one or more sputter sources are configured to sputter the first element from a first target and wherein the one or more sputter sources include one or more first magnets for generating a first magnetic field through the first target and a first motor configured to change a first distance between the first target and the one or more first magnets; wherein the one or more sputter sources are configured to sputter the second element from a second target and wherein the one or more sputter sources include one or more second magnets for generating a second magnetic field through the second target, and a second motor configured to change a second distance between the second target and the one or more second magnets; and wherein the one or more operation parameters include a distance ratio between the first distance and the second distance, and wherein the control device is configured to control the operation of the one or more sputter sources by controlling the first distance and the second distance in accordance with the distance ratio.

In Example 156, the sputter system of any one of Examples 149 to 155 can optionally further include: a vacuum chamber; and a device (e.g., a mass flow controller and/or a gate) configured to control a pressure with the vacuum chamber; wherein the one or more operation parameters include a pressure value of the pressure, and wherein the control device is configured to control the operation of the one or more sputter sources by controlling the device to control the pressure in accordance with the pressure value.

In Example 157, the sputter system of any one of Examples 149 to 156 can optionally further include: a substrate holder on which a substrate can be placed; and a motor configured to drive the substrate holder to rotate in accordance with a set rotation speed; wherein the control device of the sputter controller is configured to set the rotation speed based on the first power and the second power.

In Example 158, the sputter system of any one of Examples 149 to 157 can optionally further include: a vacuum chamber; and a device (e.g., a mass flow controller and/or a gate) configured to define an oxygen flow into the vacuum chamber; wherein the control device of the sputter controller is configured to control the device to define the oxygen flow depending on the one or more operation parameters.

Example 159 is a dual loop control method including: sputtering at least a first element (e.g., Bi) and a second element (e.g., Fe) to deposit, on a substrate, a material layer including the first element and the second element; and during sputtering the first element and the second element, controlling the sputtering via a first control loop and a second control loop; wherein the first control loop includes: (e.g., continuously (e.g., at predefined (e.g., regular) time intervals)) detecting a temperature of the substrate, and controlling the sputtering based on the temperature of the substrate; wherein the second control loop includes: (e.g., continuously (e.g., at predefined (e.g., regular) time intervals)) detecting plasma properties associated with sputtering the first element and/or the second element, and controlling the sputtering based on the plasma properties.

In Example 160, the dual loop control method of Example 159 can optionally further include: heating the substrate to a set temperature prior to sputtering the first element and the second element.

In Example 161, the subject matter of Example 160 can optionally include that the set temperature has a temperature value less than a threshold value which represents a vapor pressure of the first element at a working pressure of an atmosphere in which the first element and the second element are sputtered.

In Example 162, the subject matter of any one of Examples 159 to 161 can optionally include that sputtering the first element and the second element includes sputtering the first element and the second element in an atmosphere including oxygen (e.g., by reactively co-sputtering the first element and the second element) (the atmosphere optionally further including an inert gas).

In Example 163, the subject matter of any one of Examples 159 to 162 can optionally include that sputtering the first element and the second element includes: co-sputtering the first element from a first sputter target which substantially consists of the first element and the second element from a second sputter target different from the first sputter target, wherein the second sputter target substantially consists of an oxide of the second element; or co-sputtering the first element from a first sputter target which substantially consists of an oxide of the first element and the second element from a second sputter target different from the first sputter target, wherein the second sputter target substantially consists of the second element; or co-sputtering the first element from a first sputter target which substantially consists of an oxide of the first element and the second element from a second sputter target different from the first sputter target, wherein the second sputter target substantially consists of an oxide of the second element.

In Example 164, the subject matter of any one of Examples 159 to 163 can optionally include that sputtering the first element and the second element includes: sputtering the first element from a first sputter source and sputtering the second element from a second sputter source different from the first sputter source; or sputtering the first element from a first target of a common sputter source and sputtering the second element from a second target of the common sputter source; or sputtering the first element and the second element from a common target.

In Example 165, the subject matter of any one of Examples 159 to 164 can optionally include that the first control loop includes: determining, whether the temperature of the substrate changes, and in the case that it is determined that the temperature of the substrate changes, controlling the sputtering based on a change of the temperature of the substrate.

In Example 166, the subject matter of any one of Examples 159 to 165 can optionally include that the temperature of the substrate and the plasma properties are continuously detected during sputtering the first element and the second element.

In Example 167, the subject matter of Example 166 can optionally include that the temperature of the substrate is continuously detected according to a first (e.g., regular) cycle and wherein the plasma properties are continuously detected according to a second (e.g., regular) cycle, wherein a length of the first cycle is greater than a length of the second cycle.

In Example 168, the subject matter of any one of Examples 159 to 167 can optionally include that a cycle of the second control loop is shorter than a cycle of the first control loop.

In Example 169, the subject matter of any one of Examples 159 to 168 can optionally include that detecting plasma properties associated with sputtering the first element and/or the second element includes: optically detecting plasma properties associated with sputtering the first element and/or the second element (e.g., using optical emission spectroscopy (OES) (e.g., via OES imaging), interferometry, atomic absorption spectroscopy, and/or laser-induced fluorescence, etc.).

In Example 170, the subject matter of any one of Examples 159 to 97 can optionally include that the first element is bismuth and the second element is iron.

In Example 171, the subject matter of Example 160 in combination with Example 168 or 170 can optionally include that the set temperature has a temperature value below 630° C. (e.g., below 600° C.).

In Example 172, the subject matter of Example 161 in combination with any one of Examples 168 to 171 can optionally include that the threshold value is, at a working pressure of about 0.2*10⁻² mbar, about 630° C.

In Example 173, the subject matter of any one of Examples 159 to 172 can optionally include that the material layer includes a predefined phase which includes the first element and the second element; and wherein the method further includes: during sputtering the first element and the second element, rotating the substrate with a rotation speed equal to or greater than a predefined rotation speed which indicates that in one rotation (revolution) of the substrate a partial layer of the material layer is formed with a thickness of (about) a lattice constant of a crystal structure associated with the predefined phase.

In Example 174, the subject matter of Example 173 in combination with any one of Examples 168 to 172 can optionally include that the predefined phase is bismuth ferrite (BiFeO₃).

In Example 175, the subject matter of Example 173 or 174 can optionally include that sputtering the first element and the second element includes sputtering the first element and the second element to impinge off-center on the substrate.

In Example 176, the subject matter of Example 175 can optionally include that the substrate is a wafer; and wherein the first element and the second element are sputtered to impinge on the wafer at about a middle radius of the wafer.

In Example 177, the subject matter of Example 175 or 176 can optionally include that sputtering the first element and the second element includes confocally co-sputtering the first element and the second element with the focus being off-center on the substrate.

In Example 178, the subject matter of Example 175 or 176 can optionally include that sputtering the first element and the second element includes sputtering the first element to impinge off-center on the substrate having a first focus and sputtering the second element to impinge off-center on the substrate having a second focus different from the first focus.

In Example 179, the subject matter of any one of Examples 159 to 178 can optionally include that controlling the sputtering based on the temperature of the substrate includes controlling an oxygen supply based on the temperature of the substrate.

In Example 180, the subject matter of any one of Examples 159 to 179 can optionally include that sputtering the first element and the second element includes sputtering the first element in accordance with a first power and the second element in accordance with a second power; and wherein controlling the sputtering based on the temperature of the substrate includes: determining, based on the temperature of the substrate, a power ratio between the first power and the second power, and controlling the first power and the second power in accordance with the power ratio.

In Example 181, the subject matter of any one of Examples 159 to 180 can optionally include that sputtering the first element includes radio frequency (RF) sputtering the first element in accordance with a first power and a first power frequency; wherein sputtering the second element includes direct-current (DC) sputtering the second element in accordance with a second power; and wherein controlling the sputtering based on the temperature of the substrate includes: determining, based on the temperature of the substrate, a power ratio between the first power and the second power, and controlling the first power and the second power in accordance with the power ratio, and/or determining, based on the temperature of the substrate, a frequency value of the first power frequency and controlling the sputtering of the first element in accordance with the frequency value.

In Example 182, the subject matter of any one of Examples 159 to 181 can optionally include that sputtering the second element includes radio frequency (RF) sputtering the second element in accordance with a second power and a second power frequency; wherein sputtering the first element includes direct-current (DC) sputtering the first element in accordance with a first power; and wherein controlling the sputtering based on the temperature of the substrate includes: determining, based on the temperature of the substrate, a power ratio between the first power and the second power, and controlling the first power and the second power in accordance with the power ratio, and/or determining, based on the temperature of the substrate, a frequency value of the second power frequency and controlling the sputtering of the second element in accordance with the frequency value.

In Example 183, the subject matter of any one of Examples 159 to 180 can optionally include that sputtering the first element includes radio frequency (RF) sputtering the first element in accordance with a first power and a first power frequency; wherein sputtering the second element includes radio frequency (RF) sputtering the second element in accordance with a second power and a second power frequency; and wherein controlling the sputtering based on the temperature of the substrate includes: determining, based on the temperature of the substrate, a power ratio between the first power and the second power, and controlling the first power and the second power in accordance with the power ratio, and/or determining, based on the temperature of the substrate, a frequency ratio between the first power frequency and the second power frequency and controlling the sputtering of the first element and the second element in accordance with the frequency ratio.

In Example 184, the subject matter of any one of Examples 159 to 183 can optionally include that sputtering the first element and the second element includes sputtering the first element and the second element in an atmosphere; and wherein the controlling the sputtering based on the temperature of the substrate includes: determining, based on the temperature of the substrate, a pressure value representing a pressure of the atmosphere and controlling the pressure of the atmosphere in accordance with the pressure value.

In Example 185, the subject matter of any one of Examples 159 to 184 can optionally include that controlling the sputtering based on the plasma properties includes controlling an oxygen supply based on the plasma properties.

In Example 186, the subject matter of any one of Examples 159 to 185 can optionally include that sputtering the first element and the second element includes sputtering the first element in accordance with a first power and the second element in accordance with a second power; and wherein controlling the sputtering based on the plasma properties includes: determining, based on the plasma properties, a power ratio between the first power and the second power, and controlling the first power and the second power in accordance with the power ratio.

In Example 187, the subject matter of any one of Examples 159 to 186 can optionally include that sputtering the first element includes radio frequency (RF) sputtering the first element in accordance with a first power and a first power frequency; wherein sputtering the second element includes direct-current (DC) sputtering the second element in accordance with a second power; and wherein controlling the sputtering based on the plasma properties includes: determining, based on the plasma properties, a power ratio between the first power and the second power, and controlling the first power and the second power in accordance with the power ratio, and/or determining, based on the plasma properties, a frequency value of the first power frequency and controlling the sputtering of the first element in accordance with the frequency value.

In Example 188, the subject matter of any one of Examples 159 to 187 can optionally include that sputtering the second element includes radio frequency (RF) sputtering the second element in accordance with a second power and a second power frequency; wherein sputtering the first element includes direct-current (DC) sputtering the first element in accordance with a first power; and wherein controlling the sputtering based on the plasma properties includes: determining, based on the plasma properties, a power ratio between the first power and the second power, and controlling the first power and the second power in accordance with the power ratio, and/or determining, based on the plasma properties, a frequency value of the second power frequency and controlling the sputtering of the second element in accordance with the frequency value.

In Example 189, the subject matter of any one of Examples 159 to 186 can optionally include that sputtering the first element includes radio frequency (RF) sputtering the first element in accordance with a first power and a first power frequency; wherein sputtering the second element includes radio frequency (RF) sputtering the second element in accordance with a second power and a second power frequency; and wherein controlling the sputtering based on the plasma properties includes: determining, based on the plasma properties, a power ratio between the first power and the second power, and controlling the first power and the second power in accordance with the power ratio, and/or determining, based on the plasma properties, a frequency ratio between the first power frequency and the second power frequency and controlling the sputtering of the first element and the second element in accordance with the frequency ratio.

In Example 190, the subject matter of any one of Examples 159 to 189 can optionally include that sputtering the first element and the second element includes sputtering the first element and the second element in an atmosphere; and wherein the controlling the sputtering based on the plasma properties includes: determining, based on the plasma properties, a pressure value representing a pressure of the atmosphere and controlling the pressure of the atmosphere in accordance with the pressure value.

Example 191 is a sputter controller including: a power supply configured to operate one or more sputter sources, wherein the one or more sputter sources are configured to sputter at least a first element and a second element; and a control device configured to: (e.g., continuously (e.g., at predefined (e.g., regular) time intervals)) receive plasma data representing plasma properties associated with sputtering the first element and/or the second element; determine, based on the plasma data, one or more operation parameters of the one or more sputter sources; control the power supply based on the one or more operation parameters; (e.g., continuously (e.g., at predefined (e.g., regular) time intervals)) receive temperature data representing a temperature of the material layer; determine, whether the temperature of the substrate changes; in the case that it is determined that the temperature of the substrate changes, adapt the one or more operation parameters based on a change of the temperature of the substrate; and control the power supply based on the adapted one or more operation parameters.

In Example 192, the subject matter of Example 191 can optionally include that the temperature data includes the temperature of the substrate; and/or wherein the temperature data includes the temperature of a heater (e.g., a resistive heater and/or a lamp array) configured to heat the substrate to set temperature.

Example 193 is a sputter system including: the sputter controller according to Example 191 or 192; and the one or more sputter sources.

In Example 194, the sputter system of Example 193 can optionally further include: a temperature sensor configured to detect a temperature representing the temperature of the substrate and to provide temperature data in accordance with the detected temperature to the sputter controller.

In Example 195, the subject matter of Example 194 can optionally include that the temperature sensor is configured to detect the temperature of the substrate; and/or wherein the sputter system further includes a heater configured to heat the substrate to a set temperature and wherein the temperature sensor is configured to detect a temperature representing a temperature of the substrate.

In Example 196, the sputter system of any one of Examples 193 to 195 can optionally further include: a substrate holder on which a substrate can be placed; and a motor configured to drive the substrate holder to rotate in accordance with a set rotation speed; wherein the control device of the sputter controller is configured to set the rotation speed based on the one or more operation parameters.

In Example 197, the sputter system of any one of Examples 193 to 196 can optionally further include: a vacuum chamber; and a device (e.g., a mass flow controller and/or a gate) configured to define an oxygen flow into the vacuum chamber; that the control device of the sputter controller is configured to control the device to define the oxygen flow depending on the one or more operation parameters.

In Example 198, the sputter system of any one of Examples 193 to 197 can optionally further include: an optical sensor configured to detect the plasma properties.

Example 199 is a method including: radio frequency (RF) sputtering a first element (e.g., Bi) in accordance with a first power frequency value; and radio frequency (RF) sputtering a second element (e.g., Fe) in accordance with a second power frequency value different from the first power frequency value.

Example 200 is a method including: radio frequency (RF) sputtering a first element (e.g., Bi or Fe) in accordance with a first power frequency value; and direct current (DC) sputtering a second element (e.g., Fe or Bi).

In Example 201, the subject matter of Example 199 or 200 can optionally include that the first element is sputtered using a first sputter source and wherein the second element is sputtered using a second sputter source; or that the first element and the second element are sputtered using a common sputter source.

Example 202 is a magnetron sputter source including: a first target having a circular shape or an annular shape, the first target including a first material; a second target having an annular shape, wherein the second target includes a second material different from the first material and is arranged concentric to the first target and is not electrically conductively connected to the first target; a magnet system configured to generate a first magnetic field through the first target and a second magnetic field through the second target, wherein a first field strength distribution of the first magnetic field is different from a second field strength distribution of the second magnetic field.

In Example 203, the subject matter of Example 202 can optionally include that the first field strength distribution and the second field strength distribution are preconfigured.

In Example 204, the subject matter of Example 203 can optionally include that the magnet system includes one or more first magnets configured to generate the first magnetic field through the first target, and one or more second magnets configured to generate the second magnetic field through the second target; and that: the one or more first magnets have a first magnetic field strength and wherein the one or more second magnets have a second magnetic field strength different from the first magnetic field strength; and/or the one or more first magnets have a geometry different from the one or more second magnets; and/or a number of magnets of the one or more first magnets is different from a number of magnets of the one or more second magnets.

In Example 205, the subject matter of Example 202 can optionally include that the magnet system includes: one or more first magnets configured to generate the first magnetic field through the first target, and one or more second magnets configured to generate the second magnetic field through the second target; and a magnet control device configured to: control a distance between the one or more first magnets and the first target and/or to control a distance between the one or more second magnets and the second target; and/or control an orientation of the one or more first magnets relative to the first target and/or to control an orientation of the one or more second magnets relative to the second target.

In Example 206, the subject matter of any one of Examples 202 to 205 can optionally include that the first material includes iron and the second material includes bismuth.

In Example 207, the subject matter of Example 206 can optionally include that the first magnetic field has a first magnetic field strength and wherein the second magnetic field has a second magnetic field strength greater than the first magnetic field strength.

In Example 208, the magnetron sputter source of any one of Examples 202 to 207 can optionally further include: a third target having an annular shape, wherein the third target includes a third material different from the first material and the second material, and wherein the third target is arranged concentric to the second target and is not electrically conductively connected to the first target and the second target.

In Example 209, the subject matter of Example 208 can optionally include that the magnet system is configured to generate a third magnetic field through the third target, wherein a third field strength distribution of the third magnetic field is different from the second field strength distribution of the second magnetic field and the first field strength distribution of the first magnetic field.

In Example 210, the subject matter of Example 208 or 209 can optionally include that the first target substantially consists of bismuth, wherein the second target substantially consists of iron, and wherein the third target substantially consists of bismuth ferrite; or that the first target substantially consists of bismuth, wherein the second target substantially consists of bismuth ferrite, and wherein the third target substantially consists of titanium.

Example 211 is a method including: depositing a material layer on a substrate which rotates with a rotation speed equal to or greater than a predefined rotation speed, wherein the material layer includes at least a first element (e.g., Bi) and a second element (e.g., Fe) in a predefined phase; wherein the predefined rotation speed indicates that in one rotation (revolution) of the substrate a partial layer of the material layer is formed with a thickness of (about) a lattice constant of a crystal structure associated with the predefined phase.

In Example 212, the method of Example 211 can optionally further include: wherein depositing the material layer includes generating a deposition material stream for deposition on the substrate, wherein the deposition material stream includes the first element and the second element.

In Example 213, the method of Example 212 can optionally further include: wherein the deposition material stream is generated in an atmosphere including oxygen (e.g., by reactively co-sputtering the first element and the second element) (the atmosphere optionally further including an inert gas) or wherein the deposition material stream includes oxygen (e.g., in the case of two sputter targets: the first sputter target may include an oxide of the first element and/or the second sputter target may include an oxide of the second element; or in the case of a single sputter targets: the common sputter target may include an oxide of the first element and second element).

In Example 214, the subject matter of Example 212 or 213 can optionally include that the deposition material stream is generated to impinge off-center on the substrate.

In Example 215, the subject matter of Example 214 can optionally include that the substrate is a wafer; and that the deposition material stream is generated to impinge on the wafer at about a middle radius of the wafer.

In Example 216, the subject matter of any one of Examples 212 to 215 can optionally include that generating the deposition material stream includes confocally co-sputtering the first element and the second element with the focus being off-center on the substrate.

In Example 217, the subject matter of any one of Examples 212 to 216 can optionally include that generating the deposition material stream includes generating a first deposition material stream by sputtering the first element and generating a second deposition material stream by sputtering the second element.

In Example 218, the subject matter of Examples 214 and 217 can optionally include that the first deposition material stream is generated to impinge off-center on the substrate having a first focus and that the second deposition material stream is generated to impinge off-center on the substrate having a second focus different from the first focus.

In Example 219, the method of any one of Examples 212 to 218 can optionally further include: heating the substrate to a set temperature value prior to depositing the material layer on the substrate.

In Example 220, the subject matter of Examples 212 and 219 can optionally include that the material layer includes the first element and the second element in a predefined atomic ratio; wherein the first element has a higher temperature-dependent re-evaporation rate from the substrate and/or the material layer than the second element; that the deposition material stream includes an atomic ratio of the first element to the second element higher than the predefined atomic ratio; and that the temperature value is set to evaporate atoms of the first element from the substrate and/or the material layer such that the material layer has the predefined atomic ratio of the first element and the second element.

In Example 221, the subject matter of Example 220 can optionally include that the temperature is set to a temperature value equal to or greater than a threshold value which represents a vapor pressure of the first element at a working pressure of an atmosphere in which the material layer is to be deposited.

In Example 222, the method of Examples 212 and 219 can optionally further include that the temperature is set to a temperature value less than a threshold value which represents a vapor pressure of the first element at a working pressure of an atmosphere in which the material layer is to be deposited.

In Example 223, the subject matter of any one of Examples 211 to 222 can optionally include that depositing the material layer includes sputtering the first element in accordance with a first power and the second element in accordance with a second power to deposit the material layer on the substrate; and that the method further includes: (e.g., continuously (e.g., at predefined (e.g., regular) time intervals)) detecting a temperature of the substrate, and controlling the first power and the second power to adapt a power ratio between the first power and the second power based on the temperature of the substrate.

In Example 224, the subject matter of any one of Examples 211 to 223 can optionally include that depositing the material layer includes sputtering the first element in accordance with a first power and the second element in accordance with a second power to deposit the material layer on the substrate; and that the method further includes: (e.g., continuously (e.g., at predefined (e.g., regular) time intervals)) detecting plasma properties associated with sputtering the first element and/or the second element, and controlling the first power and the second power to adapt the power ratio between the first power and the second power based on the plasma properties.

In Example 225, the method of Example 223 or 224 can optionally further include: controlling the rotation speed based on the first power and the second power.

In Example 226, the subject matter of any one of Examples 211 to 225 can optionally include that the first element is bismuth and the second element is iron.

In Example 227, the subject matter of Examples 213 and 226 can optionally include that the predefined phase is bismuth ferrite (BiFeO₃).

In Example 228, the subject matter of Example 219 in combination with Example 226 or 227 can optionally include that the threshold value is, at a working pressure of about 0.2*10⁻² mbar, about 630° C.

In Example 229, the method of any one of Examples 211 to 228 can optionally further include: during depositing the material layer, irradiating the substrate and/or the partial layer using a linear lamp array.

Example 230 is a method including: depositing a material layer on a substrate, wherein the material layer includes at least a first element (e.g., Bi) and a second element (e.g., Fe) in a predefined phase; and during depositing the material layer: irradiating the substrate and/or deposited material using a linear lamp array, and rotating the substrate during irradiating the substrate and/or deposited material using the linear lamp array.

Example 231 is a method including: depositing a material layer on a substrate, wherein the material layer includes at least a first element (e.g., Bi) and a second element (e.g., Fe) in a predefined phase; and after depositing the material layer: irradiating the material layer using a linear lamp array, and rotating the substrate during irradiating the material layer using the linear lamp array.

Example 232 is a method including: forming a complementary metal-oxide-semiconductor, CMOS, structure at least one of in or over a substrate; forming a metallization structure over the CMOS structure; forming one or more memristive devices over the metallization structure, wherein forming the one or more memristive devices includes: reactively co-sputtering bismuth, iron, and titanium in an atmosphere including oxygen (the atmosphere optionally further including an inert gas) to generate a material layer including (e.g., substantially consisting of) titanium doped bismuth ferrite (Ti:BiFeO₃); or co-sputtering bismuth, iron, oxygen, and titanium to generate a material layer including (e.g., substantially consisting of) titanium doped bismuth ferrite (Ti:BiFeO₃).

In Example 233, the method of Example 232 can optionally further include: forming a metal layer over the metallization structure prior to forming the one or more memristive devices.

In Example 234, the method of Example 233 can optionally further include: during or after forming the one or more memristive devices, irradiating the material layer using a linear lamp array, wherein the metal layer is configured to reflect at least 70% (e.g., at least 90%) of incident radiation from the linear lamp array.

In Example 235, the subject matter of any one of Examples 232 to 234 can optionally include that co-sputtering bismuth, iron, oxygen, and titanium includes sputtering at least one of bismuth, iron, and/or titanium from an oxidic target (e.g., bismuth oxide (e.g., Bi₂O₃) and/or iron oxide (e.g., Fe₂O₃) and/or titanium oxide (e.g., TiO₂).

In Example 236, the subject matter of any one of Examples 232 to 235 can optionally include that co-sputtering bismuth, iron, oxygen, and titanium includes sputtering bismuth, iron, oxygen, and titanium from a common target.

In Example 237, the subject matter of any one of Examples 232 to 236 can optionally include that reactively co-sputtering bismuth, iron, and titanium includes: co-sputtering bismuth from a bismuth target, iron from an iron target, and titanium from a titanium target; or co-sputtering bismuth, iron, and titanium from a common target; or co-sputtering bismuth, iron, and titanium from a common target, bismuth from a bismuth target, and iron from an iron target; or co-sputtering bismuth, iron, and titanium from a first target, and bismuth and iron from a second target different from the first target; or co-sputtering bismuth and titanium from a common target and iron from an iron target; or co-sputtering iron and titanium from a common target and bismuth from a bismuth target; or co-sputtering bismuth and titanium from a first target and iron and titanium from a second target.

In Example 238, the subject matter of any one of Examples 232 to 237 can optionally include that the one or more memristive devices are formed at a temperature of the substrate equal to or greater than 630° C.

In Example 239, the subject matter of any one of Examples 232 to 238 can optionally include that the one or more memristive devices are formed at a temperature of the substrate below 630° C.; that bismuth is sputtered in accordance with a first power and that iron is sputtered in accordance with a second power; and wherein the method further includes during the sputtering: (e.g., continuously (e.g., at predefined (e.g., regular) time intervals)) detecting a temperature of the substrate, and controlling the sputtering based on the temperature of the substrate; and/or (e.g., continuously (e.g., at predefined (e.g., regular) time intervals)) detecting plasma properties associated with the sputtering, and controlling the sputtering based on the plasma properties.

In Example 240, the subject matter of Example 239 can optionally include that the material layer has a predefined titanium concentration; that bismuth is sputtered from a first sputter target in accordance with the first power and wherein iron is sputter from a second sputter target in accordance with the second power, the second sputter target being different from the first sputter target; wherein further bismuth and iron are sputtered from a third sputter target in accordance with a third power, wherein the third sputter target is different from the first sputter target and the second sputter target, and that the third sputter target includes bismuth, iron, and titanium; and wherein the method further includes during the sputtering: controlling the third power such that the material layer has the predefined titanium concentration.

Example 241 is a non-volatile computer-readable medium including instructions which, when executed by one or more processors, cause the one or more processors to carry out the method according to any one of Examples 1 to 49, 56 to 73, 86 to 107, 115 to 142, 159 to 190, 199 to 201, and/or 211 to 240.

Example 242 is a sputter source (e.g., magnetron sputter source) including: a plurality of sputter targets; and a target control device configured to: control a position and/or orientation of at least one sputter target of the plurality of sputter targets relative to the other ones; and/or rotate at least one sputter target of the plurality of sputter targets in plane.

In Example 243, the subject matter of Example 242 may optionally further include that each sputter target of the plurality of sputter targets is strip-shaped.

In Example 244, the subject matter of Example 242 or 243 may optionally further include the plurality of sputter targets is arranged as an alternating sequence of targets including at least the first element and targets including at least the second element.

In Example 245, the sputter source of any one of Examples 242 to 244 may, where applicable, include the features of any one of Examples 202 to 210.

In Example 246, the method according to any one of Examples 1 to 49, 56 to 73, 86 to 107, 115 to 142, 159 to 190, 199 to 201, and/or 211 to 240 may, where applicable, optionally further include: controlling a position and/or orientation of at least one sputter target of a plurality of sputter targets relative to the other ones; and/or rotate at least one sputter target of the plurality of sputter targets in plane.

Example 247 is a wafer chuck including: a base plate for carrying a wafer, the base plate having an inner region and an outer region, the inner region being closer to a center of the base plate than the outer region; and one or more resistive heaters for heating the base plate, wherein the one or more resistive heaters are configured to generate more heat in the outer region than in the inner region of the base plate.

In Example 248, the subject matter of Example 247 may optionally further include that the one or more resistive heaters include one or more electrically conducting lines configured such that a resistance of the one or more electrically conducting lines is larger in the outer region than in the inner region.

In Example 249, the subject matter of Example 247 or 248 may optionally further include that the one or more resistive heaters include (e.g., the) one or more electrically conducting lines, wherein windings of the one or more electrically conducting lines in the outer region are closer to each other than windings of the one or more electrically conducting lines in the inner region.

In Example 250, any of the sputter system described with reference to one of the previous Examples may include the wafer chuck of any one of Examples 247 to 249.

In Example 251, the method according to any one of Examples 1 to 49, 56 to 73, 86 to 107, 115 to 142, 159 to 190, 199 to 201, and/or 211 to 240 may, where applicable, optionally further include heating the substrate during depositing the material layer using one or more resistive heaters which are configured to generate more heat in an outer region than in an inner region.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes, which come within the meaning and range of equivalency of the claims, are therefore intended to be embraced.

What is claimed is:

1. A method, comprising:
depositing a material layer on a substrate, wherein the material layer comprises at least a first element and a second element in a predefined atomic ratio, wherein the first element has a higher temperature-dependent re-evaporation rate from the substrate and/or the material layer than the second element;
wherein depositing the material layer comprises:
generating a deposition material stream for deposition on the substrate, wherein the deposition material stream comprises an atomic ratio of the first element to the second element higher than the predefined atomic ratio, and
setting a temperature of the substrate to evaporate atoms of the first element from the substrate and/or the material layer such that the material layer has the predefined atomic ratio of the first element and the second element.

2. The method according to claim 1,
wherein setting the temperature of the substrate comprises setting the temperature of the substrate to a temperature value equal to or greater than a lower threshold value, wherein the lower threshold value represents a vapor pressure of the first element at a working pressure of an atmosphere the deposition material stream is generated in.

3. The method according to claim 1,
wherein, in a temperature range from about 400° C. to about 800° C., the temperature-dependent re-evaporation rate of the first element from the substrate and/or the material layer is at least two times the temperature-dependent re-evaporation rate of the second element from the substrate and/or the material layer.

4. The method according to claim 1,
wherein the first element is bismuth and the second element is iron.

5. The method according to claim 4,
wherein the temperature of the substrate is set to have a temperature value in a range from about 600° C. to about 650° C.

6. A method, comprising:
determining a temperature value representing a temperature of a substrate on which a material layer comprising at least a first element and a second element in a predefined atomic ratio is to be deposited;
determining, based on the temperature value, a nominal power ratio between a first power associated with sputtering the first element and a second power associated with sputtering the second element; and
setting a first power value of the first power and a second power value of the second power in accordance with the nominal power ratio.

7. The method according to claim 6, further comprising:
depositing the material layer on the substrate, wherein the first power value and the second power value are set prior to depositing the material layer on the substrate.

8. The method according to claim 6, further comprising:
during depositing the material layer on the substrate:
detecting plasma properties associated with sputtering the first element and/or the second element,
determining an adapted nominal power ratio between the first power and the second power based on the plasma properties, and
controlling the first power and the second power in accordance with the adapted nominal power ratio.

9. A method, comprising:
sputtering at least a first element and a second element to deposit, on a substrate, a material layer comprising the first element and the second element;
during sputtering the first element and the second element:
detecting a temperature value representing a temperature of the substrate;
determining, based on the temperature value, one or more operation parameters of the sputtering; and
controlling the sputtering based on the one or more operation parameters.

10. The method according to claim 9, further comprising:
heating the substrate to a set temperature value prior to sputtering the first element and the second element, wherein the set temperature value is less than a threshold value which represents a vapor pressure of the first element at a working pressure of an atmosphere in which the material layer is deposited.

11. A method, comprising:
sputtering at least a first element and a second element to deposit, on a substrate, a material layer comprising the first element and the second element;
during sputtering the first element and the second element:
detecting plasma properties associated with sputtering the first element and/or the second element;
determining, based on the plasma properties, one or more operation parameters of the sputtering; and
controlling the sputtering based on the one or more operation parameters.

12. The method according to claim 11, further comprising:
heating the substrate to a set temperature value prior to sputtering the first element and the second element, wherein the set temperature value is less than a threshold value which represents a vapor pressure of the first element at a working pressure of an atmosphere in which the material layer is deposited.

13. The method according to claim 11,
wherein sputtering the first element and the second element comprises sputtering the first element and the second element in an atmosphere comprising oxygen;
wherein the one or more operation parameters comprise an oxygen partial pressure; and
wherein controlling the sputtering comprises controlling an oxygen supply based on the oxygen partial pressure.

14. The method according to claim 13,
wherein determining the oxygen partial pressure based on the plasma properties comprises determining one or more parameters representing electrical properties of a first plasma associated with sputtering the first element and/or a second plasma associated with sputtering the second element, and determining the oxygen partial pressure based on the one or more parameters; and/or
wherein detecting plasma properties comprises detecting a plasma emission of a first plasma associated with sputtering the first element and/or a second plasma associated with sputtering the second element, determining, based on the plasma emission, an intensity of an oxygen characteristic, wherein determining the oxygen partial pressure comprises determining the oxygen partial pressure using the oxygen characteristic.

15. The method according to claim 11,
wherein sputtering the first element and the second element comprises sputtering the first element in accordance with a first power and the second element in accordance with a second power; and
wherein the one or more operation parameters comprise a power ratio between the first power and the second power, and wherein controlling the sputtering comprises controlling the first power and the second power in accordance with the power ratio.

16. The method according to claim 11,
wherein sputtering the first element comprises radio frequency sputtering the first element in accordance with a first power and a first power frequency;
wherein sputtering the second element comprises direct-current sputtering the second element in accordance with a second power; and
wherein:
the one or more operation parameters comprise a power ratio between the first power and the second power and wherein controlling the sputtering comprises controlling the first power and the second power in accordance with the power ratio, and/or
the one or more operation parameters comprise a frequency value of the first power frequency and wherein controlling the sputtering comprises controlling the sputtering of the first element in accordance with the frequency value.

17. The method according to claim 11,
wherein sputtering the first element comprises radio frequency sputtering the first element in accordance with a first power and a first power frequency;
wherein sputtering the second element comprises radio frequency sputtering the second element in accordance with a second power and a second power frequency; and
wherein the one or more operation parameters comprise a frequency ratio between the first power frequency and the second power frequency and wherein controlling the sputtering comprises controlling the sputtering of the first element and the second element in accordance with the frequency ratio.

18. The method according to claim 11,
wherein sputtering the first element comprises magnetron sputtering the first element from a first target and wherein sputtering the second element comprises magnetron sputtering the second element from a second target; and
wherein the one or more operation parameters comprise a distance ratio between a first distance and a second distance, wherein the first distance is a distance between the first target and one or more first magnets associated with magnetron sputtering the first element and wherein the second distance is a distance between the second target and one or more second magnets associated with magnetron sputtering the second element.

19. The method according to claim 11,
wherein sputtering the first element and the second element comprises sputtering the first element and the second element in an atmosphere; and
wherein the one or more operation parameters comprise a pressure value representing a pressure of the atmosphere, and wherein controlling the sputtering comprises controlling the pressure of the atmosphere in accordance with the pressure value.

20. The method according to claim 11,
wherein the first element is bismuth and the second element is iron.
